(19) United States
(12) Patent Application Publication
(10) Pub. No.: US 2026/0288009 A1
(43) Pub. Date: Sep. 24, 2026

(54) LIGHT SOURCE APPARATUS

(71) Applicant: Lasertec Corporation, Yokohama (JP)

(72) Inventors: Masayasu NISHIZAWA, Yokohama (JP); Mizuki KOBAYASHI, Yokohama (JP); Junya KAWAGUCHI, Yokohama (JP); Masaki KOICHI, Yokohama (JP)

(21) Appl. No.: 19/570,908

(22) Filed: Mar. 18, 2026

(30) Foreign Application Priority Data
Mar. 24, 2025 (JP) 2025-048146

(51) Int. Cl. G03F 7/20

(52) U.S. Cl. CPC G03F 7/2008; G03F 7/2004

(57) ABSTRACT

Provided is a light source apparatus that can be kept compact. The light source apparatus according to the present disclosure includes: a target holding unit having a hold plane for holding a target member that generates plasma by being irradiated with excitation light; and a mirror opposing the plasma generated from the target member held on the hold plane and configured to reflect generated light generated from the plasma. The mirror has a missing part for passing an optical axis of the excitation light to be radiated onto the target member held on the hold plane or an extension line of the optical axis.

### INCORPORATION BY REFERENCE

This application is based upon and claims the benefit of priority from Japanese Patent Application No. 2025-048146, filed on Mar. 24, 2025, the disclosure of which is incorporated herein in its entirety by reference for all purposes.

### BACKGROUND

The present disclosure relates to a light source apparatus.

Patent Literature 1 discloses a light source apparatus configured to generate Extreme Ultraviolet (EUV) light by using a crucible scheme.

[Patent Literature 1] Japanese Unexamined Patent Application Publication No. 2021-001924

### SUMMARY

As for light source apparatuses for extracting light from plasma generated by radiating excitation light onto a target member held on a hold plane of a target holding unit such as a crucible, a drum, or a tape, it is desirable in some situations to realize a space-saving (compact) structure while maintaining performance thereof.

An object of the present disclosure is to solve the abovementioned problem and to provide a light source apparatus capable of striking a balance between a layout and the performance.

A light source apparatus according to the present disclosure includes: a target holding unit having a hold plane for holding a target member that generates plasma by being irradiated with excitation light; and a mirror opposing the plasma generated from the target member held on the hold plane and configured to reflect generated light generated from the plasma, in which the mirror has a missing part for passing an optical axis of the excitation light to be radiated onto the target member held on the hold plane or an extension line of the optical axis.

The light source apparatus described above may be configured in such a manner that a first focused point formed by the mirror corresponds to an irradiation position of the excitation light on the target member, and a second focused point formed by the mirror corresponds to a position outside the target holding unit.

The light source apparatus described above may be configured in such a manner that the target member moves together with movement of the hold plane, and the excitation light is radiated onto the target member at such an incident angle that an angle formed between a principal optical axis of the excitation light when the principal optical axis is projected on a plane and a straight line including a moving direction of the target member falls in a range of 0° to 60°, the plane including the moving direction of the target member on the hold plane at an irradiation position of the excitation light and a normal line to the hold plane.

The light source apparatus described above may be configured in such a manner that the target member moves together with movement of the hold plane, and the excitation light is radiated onto the target member at such an incident angle that an angle formed between a principal optical axis of the excitation light when the principal optical axis is projected on a plane and a normal line to the hold plane at an irradiation position of the excitation light falls in a range of 0° to 10°, the plane including a moving direction of the target member on the hold plane at the irradiation position of the excitation light and the normal line to the hold plane.

The light source apparatus described above may be configured in such a manner that the mirror forms a first focused point corresponding to an irradiation position of the excitation light on the target member, the target member moves together with movement of the hold plane, and an angle formed between a straight line intersected by a plane and the hold plane at the irradiation position and a normal line to a straight line including a moving direction of the target member on the hold plane at the irradiation position falls in a range of 0° to 45°, the plane including a principal optical axis of the generated light traveling from the first focused point toward the mirror and a principal optical axis of the generated light reflected by the mirror.

The light source apparatus described above may be configured in such a manner that the principal optical axis of the generated light reflected by the mirror is positioned on an upper side in vertical directions relative to the plane.

The light source apparatus described above may be configured in such a manner that the principal optical axis of the generated light reflected by the mirror is positioned on a lower side in vertical directions relative to the plane.

The light source apparatus described above may be configured in such a manner that a principal optical axis of the excitation light to be radiated onto the target member does not overlap a principal optical axis of the generated light traveling from the plasma toward the mirror.

The light source apparatus described above may be configured in such a manner that a principal optical axis of the excitation light to be radiated onto the target member and a principal optical axis of the generated light traveling from the plasma toward the mirror have regions that substantially coincide with each other.

The light source apparatus described above may be configured in such a manner that an angle formed between a direction orthogonal to the hold plane at an irradiation position of the excitation light and the optical axis of the excitation light is smaller than an angle formed between the direction orthogonal to the hold plane at the irradiation position and an optical axis of the generated light traveling from the plasma toward the mirror.

The light source apparatus described above may be configured in such a manner that a portion of an outer circumferential surface of an excitation light cover covering at least a portion of an optical path of the excitation light is in contact with a portion of an inner circumferential surface of a generated light cover covering at least a portion of an optical path of the generated light.

The light source apparatus described above may further include a filter that is in contact with an outer circumferential surface of an excitation light cover covering at least a portion of an optical path of the excitation light and with an inner circumferential surface of a generated light cover covering at least a portion of an optical path of the generated light.

The light source apparatus described above may be configured in such a manner that the hold plane moves as a result of the target holding unit rotating on a rotation axis, and the target member moves to the irradiation position in conjunction with the moving of the hold plane.

According to the present disclosure, it is possible to provide the light source apparatus capable of striking balance between a layout and the performance.

The above and other objects, features and advantages of the present disclosure will become more fully understood from the detailed description given hereinbelow and the accompanying drawings.

### BRIEF DESCRIPTION OF DRAWINGS

FIG. 1 is a cross-sectional view showing an example of a light source apparatus according to a first embodiment;

FIG. 2 is a plan view showing an example of a collector mirror serving as a mirror in the light source apparatus according to the first embodiment;

FIG. 3 is a plan view showing another example of the collector mirror serving as the mirror in the light source apparatus according to the first embodiment;

FIG. 4 is a drawing for explaining an alternative positional arrangement of the collector mirror in the light source apparatus according to the first embodiment;

FIG. 5 is a cross-sectional view showing an example of a light source apparatus according to a first modified example of the first embodiment;

FIG. 6 is a cross-sectional view showing an example of a light source apparatus according to a second modified example of the first embodiment;

FIG. 7 is a cross-sectional view showing examples of optical path covers in the light source apparatus according to the second modified example of the first embodiment, showing a cross-section taken at line A-A in FIG. 6;

FIG. 8 is a cross-sectional view showing examples of the optical path covers and a filter in the light source apparatus according to the second modified example of the first embodiment;

FIG. 9 is a cross-sectional view showing an example of a light source apparatus according to a second embodiment;

FIG. 10 is a plan view showing examples of a target holding unit, a generation unit, and an output optical system in the light source apparatus according to the second embodiment;

FIG. 11 is another plan view showing the examples of the target holding unit, the generation unit, and the output optical system in the light source apparatus according to the second embodiment;

FIG. 12 is a cross-sectional view showing an example of a target member held by an inside wall of a cylindrical part of the target holding unit in the light source apparatus according to the second embodiment;

FIG. 13 is a cross-sectional view showing another example of the target member held by the inside wall of the cylindrical part of the target holding unit in the light source apparatus according to the second embodiment;

FIG. 14 is a cross-sectional view showing yet another example of the target member held by the inside wall of the cylindrical part of the target holding unit in the light source apparatus according to the second embodiment;

FIG. 15 is a cross-sectional view showing yet another example of the target member held by the inside wall of the cylindrical part of the target holding unit in the light source apparatus according to the second embodiment;

FIG. 16 is a cross-sectional view showing yet another example of the target member held by the inside wall of the cylindrical part of the target holding unit in the light source apparatus according to the second embodiment;

FIG. 17 is a cross-sectional view showing an example of a target holding unit in a light source apparatus according to a first modified example of the second embodiment;

FIG. 18 is a cross-sectional view showing an example of a light source apparatus according to a third embodiment;

FIG. 19 is a cross-sectional view showing an example of a cylindrical part of a target holding unit in a light source apparatus according to a first modified example of the third embodiment;

FIG. 20 is a cross-sectional view showing an example of a positional arrangement of a sensor in a light source apparatus according to a second modified example of the third embodiment;

FIG. 21 is a cross-sectional view showing an example of a debris storing container in a light source apparatus according to a third modified example of the third embodiment;

FIG. 22 is a cross-sectional view showing an example of a light source apparatus according to a fourth embodiment;

FIG. 23 is a cross-sectional view showing an example of a cylindrical part of a target holding unit in a light source apparatus according to a first modified example of the fourth embodiment;

FIG. 24 is a cross-sectional view showing an example of a positional arrangement of a sensor in a light source apparatus according to a second modified example of the fourth embodiment;

FIG. 25 is a cross-sectional view showing an example of a debris storing container in a light source apparatus according to a third modified example of the fourth embodiment;

FIG. 26 is a cross-sectional view showing an example of a light source apparatus according to a fifth embodiment; and

FIG. 27 is a cross-sectional view showing an example of a light source apparatus according to a first modified example of the fifth embodiment.

### DESCRIPTION OF EMBODIMENTS

Specific configurations of embodiments of the present disclosure will be explained below, with reference to the drawings. The following explanations indicate embodiments of the present disclosure, and the scope of the present disclosure is not limited to the following embodiments. In the explanations below, some of the elements referred to by using the same reference characters substantially represent the same features.

### First Embodiment

A light source apparatus according to a first embodiment will be explained. The light source apparatus of the present embodiment is configured to generate light such as illumination light, exposure light, or the like used in an optical apparatus such as an inspection apparatus, a review apparatus, and an exposure apparatus, or the like. The light source apparatus may integrally be provided with such an optical apparatus or may be disposed in the vicinity of such an optical apparatus as a separate body apart from the optical apparatus. When the optical apparatus is an inspection apparatus, the light source apparatus is configured to generate illumination light for illuminating an object to be inspected or an object to be observed by the inspection apparatus or a review apparatus. In contrast, when the optical apparatus is an exposure apparatus, the light source apparatus is configured to generate exposure light for causing light exposure for an object to be exposed to light by the exposure apparatus.

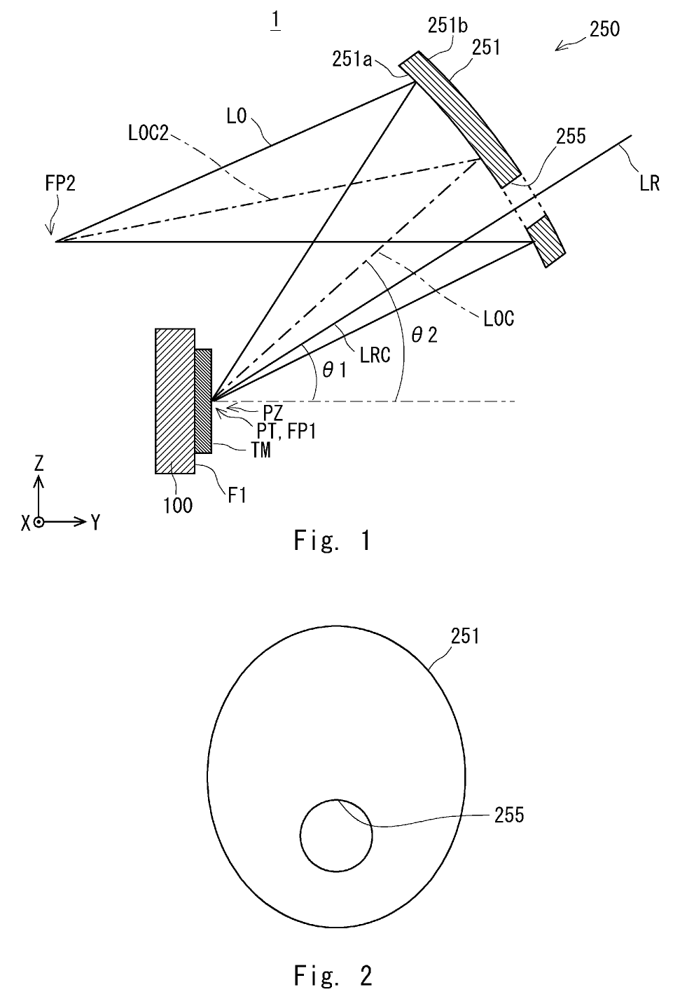

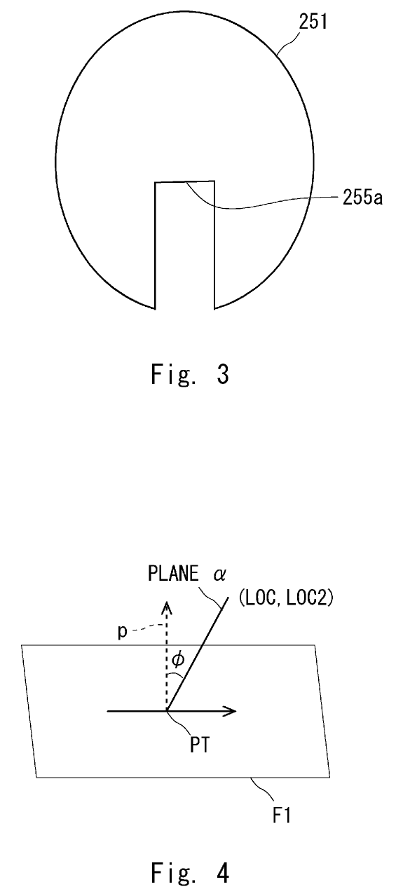

FIG. 1 is a cross-sectional view showing an example of a light source apparatus 1 according to the first embodiment. FIGS. 2 and 3 are plan views showing examples of a collector mirror 251 serving as a mirror in the light source apparatus 1 according to the first embodiment. As shown in FIG. 1, the light source apparatus 1 includes a target holding unit 100 and an output optical system 250. The target holding unit 100 has a hold plane F1. The hold plane F1 holds a target member TM. The light source apparatus 1 is configured to generate plasma PZ from the target member TM, by radiating excitation light LR onto the target member TM held by the target holding unit 100. At the time of generating the plasma PZ, light is generated from the plasma PZ. The light generated from the plasma PZ is to be used as light such as illumination light, exposure light, or the like. The light generated as a result of radiating the excitation light LR onto the target member TM will be referred to as generated light L0. For example, the generated light L0 may include EUV light. For example, the excitation light LR may include laser light including infrared (IR) light. A position within the target member TM that is irradiated with the excitation light LR will be referred to as an irradiation position PT.

For the sake of convenience in the explanations of the light source apparatus 1, an XYZ orthogonal coordinate axes system will be introduced. For example, the directions orthogonal to the hold plane F1 at the irradiation position PT will be defined as Y axis directions. The two directions that are orthogonal to the Y axis directions and are orthogonal to each other will be defined as X axis directions and Z axis directions. In the present embodiment, the Z axis directions are defined as vertical directions, i.e., gravity directions. Further, in the present embodiment, the upward direction of the gravity directions will be defined as a +Z axis direction, whereas the downward direction of the gravity directions will be defined as a -Z axis direction. Conversely, the downward direction of the gravity directions may be defined as a +Z axis direction, whereas the upward direction of the gravity directions may be defined as a -Z axis direction. In another example, horizontal directions orthogonal to the gravity directions or directions tilted from the gravity directions may be defined as Z axis directions.

In this situation, the upward direction and the downward direction include not only the strictly upward and downward directions of the gravity directions, but are also used in a sense including a measurement error at the time of measuring the upward and downward directions and a tilt that may be caused by a manufacture error occurring during the manufacture of the light source apparatus 1. The upward direction and the downward direction in this sense may be referred to as a substantially upward direction and a substantially downward direction. Further, the upward direction and the downward direction include not only the strictly upward and downward directions of the gravity directions, but are also used in a sense including the situation where the angle formed between a direction and the strictly upward direction of the gravity directions is so small (e.g., 15 degrees or smaller) that the influence of the gravity is regarded to be equal in terms of designs, and the situation where the angle formed between a direction and the strictly downward direction of the gravity directions is so small (e.g., 15 degrees or smaller) that the influence of the gravity is regarded to be equal in terms of designs. The upward direction and the downward direction in this sense may be referred to as a substantially upward direction and a substantially downward direction. Also, the substantially upward direction and the substantially downward direction may simply be referred to as an upward direction and a downward direction. The above explanations are similarly applicable to vertical, horizontal, substantially vertical, and substantially horizontal directions.

A light source apparatus 2 described in a second embodiment later will be explained by using an example in which a liquid target member TM is held by the target holding unit 100 including a container such as a crucible. In contrast, the target holding unit 100 in the light source apparatus 1 according to the present embodiment is not limited to one including a container such as a crucible and may be configured to hold a solid target member TM in a cylindrical member such as a drum, may be configured to hold a target member TM on a member having a tape-like shape, or may be configured to hold a target member TM having a tape-like shape on a member having a plate-like shape. FIG. 1 may depict a cross-section of a portion of the target holding unit 100.

As long as the target member TM is a substance that forms the plasma PZ by being irradiated with the excitation light LR, the target member TM is not limited to being a substance in a liquid state held by the target holding unit 100. Possible examples thereof may include a substance in a solid state such as a member having a tape-like shape or a solid metal. Examples of the substance in a liquid state include a molten metal obtained by melting tin (Sn) or lithium (Li); however, as long as the substance generates the plasma PZ by being irradiated with the excitation light LR, possible examples thereof are not limited to tin, lithium, and the like.

The output optical system 250 includes the collector mirror 251, which is an example of a mirror. In addition to the collector mirror 251, the output optical system 250 may further include one or more other optical members. For example, the output optical system 250 may include a second collector mirror (not shown) configured to further reflect the generated light L0 reflected by the collector mirror 251. The collector mirror 251 is configured to oppose the plasma PZ generated from the target member TM held on the hold plane F1. The collector mirror 251 includes a mirror for extracting the generated light L0 generated from the target member TM, to the outside of the light source apparatus 1. For example, the collector mirror 251 includes a spheroidal mirror. As long as the generated light L0 can be extracted to the outside of the light source apparatus 1, the collector mirror 251 is not limited to including a spheroidal mirror and may include a concave mirror or a flat mirror. The output optical system 250 has a first focused point FP1 formed by the collector mirror 251 or another optical element. The first focused point FP1 corresponds to the irradiation position PT of the excitation light LR on the target member TM. The output optical system 250 has a second focused point FP2 formed by the collector mirror 251 or another optical element. The second focused point FP2 corresponds to a prescribed position outside the target holding unit 100. With this structure, the output optical system 250 is configured to extract the generated light L0 generated from the target member TM to the outside of the light source apparatus 1. In the following sections, a principal optical axis of the generated light L0 traveling from the first focused point FP1 (the irradiation position PT) toward the collector mirror 251 will be referred to as an optical axis L0C.

The collector mirror 251 includes a reflection surface 251a and an opposite surface 251b. The opposite surface 251b is the surface on the opposite side of the reflection surface 251a. The collector mirror 251 is configured to reflect the generated light L0 on the reflection surface 251a. In this manner, the collector mirror 251 is used to extract the generated light L0 generated from the plasma PZ that resulting from the target member TM irradiated with the excitation light LR. As shown in FIG. 2, the collector mirror 251 has a through hole 255 serving as an example of a missing part. The through hole 255 penetrates the collector mirror 251 from the reflection surface 251a to the opposite surface 251b. The excitation light LR passes through the through hole 255 and is radiated onto the target member TM held on the hold plane F1. The excitation light LR may pass through a lens (not shown) provided in the through hole 255 so as to be radiated onto the target member TM held on the hold plane F1. Further, the collector mirror 251 may have the through hole 255 for passing an optical axis LRC of the excitation light LR to be radiated onto the target member TM held on the hold plane F1 or an extension line of the optical axis LRC. More specifically, it is conceivable to dispose, in the through hole 255, a portion of a generation unit including a laser generator (not shown) configured to generate and emit the excitation light LR. The configuration in which the excitation light LR is radiated onto the target member TM from the generation unit disposed in the through hole 255 is an example of the configuration in which the collector mirror 251 has the through hole 255 for passing an extension line of the optical axis LRC of the excitation light LR to be radiated onto the target member TM held on the hold plane F1.

As shown in FIG. 3, the collector mirror 251 may have a missing area 255a as a missing part for passing the optical axis LRC of the excitation light LR to be radiated onto the target member TM held on the hold plane F1 or an extension line of the optical axis LRC. As explained herein, the missing part is not limited to being the through hole 255 and may be the missing area 255a or the like, as long as the missing part is formed by gouging a portion of a periphery part of the collector mirror 251 from the rest of the periphery part.

The collector mirror 251 is disposed on the +Z axis direction side relative to the irradiation position PT on the target member TM. Accordingly, the excitation light LR may be radiated onto the irradiation position PT by passing through the through hole 255 from a position on the +Z axis direction side relative to the irradiation position PT. As a result, when the direction orthogonal to the hold plane F1 at the irradiation position PT is expressed as a Y axis direction, the optical axis LRC being the principal optical axis of the excitation light LR is tilted toward the +Z axis direction side at an angle θ1 with respect to the Y axis.

The direction of the optical axis LRC of the excitation light LR may be different from the direction of the optical axis L0C of the generated light L0 traveling from the plasma PZ toward the collector mirror 251. In other words, the optical axis LRC of the excitation light LR to be radiated onto the target member TM does not overlap the optical axis L0C of the generated light L0 traveling from the plasma PZ toward the mirror. For example, the angle θ1 formed between the direction orthogonal to the hold plane F1 at the irradiation position PT and the optical axis LRC of the excitation light LR may be smaller than an angle θ2 formed between the direction orthogonal to the hold plane F1 at the irradiation position PT and the optical axis L0C of the generated light L0 traveling from the plasma PZ toward the collector mirror 251. With this configuration, by decreasing an incident angle of the excitation light LR with respect to the target member TM, it is possible to reduce the volume in which the plasma PZ is formed. As a result, this configuration is advantageous in exercising control to make the shape of the plasma PZ a desirable shape. In addition, because it is possible to greatly tilt the collector mirror 251 with respect to the direction orthogonal to the hold plane F1 at the irradiation position PT, it is possible to increase an NA of the collector mirror 251, while preventing adhesion to the collector mirror 251 of debris of the target member TM which may result from the plasma PZ at the irradiation position PT.

The first focused point FP1 may be formed by the collector mirror 251. In that situation, the collector mirror 251 may be a spheroidal mirror. The first focused point FP1 of the collector mirror 251 corresponds to the irradiation position PT of the excitation light LR on the target member TM. The second focused point FP2 may be formed by the collector mirror 251. In that situation, the collector mirror 251 may be a spheroidal mirror. The second focused point FP2 of the collector mirror corresponds to a prescribed position outside the target holding unit 100.

With reference to FIG. 4, an example of alternative positional arrangements of the collector mirror 251 in the light source apparatus 1 according to the first embodiment will be explained. A plane α denotes a plane including the optical axis L0C being the principal optical axis of the generated light L0 traveling from the first focused point FP1 toward the collector mirror 251 and an optical axis L0C2 being the principal optical axis of the generated light L0 reflected by the reflection surface 251a of the collector mirror 251. In the situation where the target member TM moves together with the movement of the hold plane F1, it is desirable that an angle Φ formed between an intersection line of the plane α and the hold plane F1 at the irradiation position PT, and a normal line p to a straight line including the moving direction of the target member TM on the hold plane F1 at the irradiation position PT is in the range of 0° to 45°. In some examples, the angle Φ may be in the range of 0° to 30°. With this configuration, it is possible to prevent the generated light L0 reflected by the collector mirror 251 from being blocked by the target holding unit 100 or a structure in the surroundings thereof.

This advantageous effect can similarly be expected, not only in the situation where the target holding unit 100 is a container such as a crucible that allows the hold plane F1 to move as a result of rotation around a rotation axis, but also in the situation where the target holding unit 100 is a cylindrical member such as a drum that allows the hold plane F1 to move as a result of rotation on a rotation axis, and in the situation where the target holding unit 100 is a structure having a tape-like shape that allows the hold plane F1 to move as a result of a parallel displacement or the like. The abovementioned angle Φ may be either a clockwise angle or a counterclockwise angle measured by using the normal line p as a reference. In other words, the angle Φ formed between the plane α and the normal line p may be set in the abovementioned range, in such a manner that the plane α intersects the hold plane F1 either on a more upstream side or on a more downstream side of the moving direction of the target member TM. For the purpose of preventing the collector mirror 251 from becoming unclean, it may be preferable to set the angle Φ formed between the plane α and the normal line p to be in the abovementioned range, in such a manner that the plane α intersects the hold plane F1 on a more upstream side of the moving direction of the target member TM. The collector mirror 251 does not necessarily need to be a single optical element. The collector mirror 251 described above may be structured by a combination of a plurality of optical elements.

In the situation where the target member TM moves in conjunction with the moving of the hold plane F1, the angle formed between the optical axis L0C being the principal optical axis of the generated light L0 traveling from the first focused point FP1 toward the collector mirror 251 when the optical axis L0C is projected on a plane and a straight line including the moving direction of the target member TM on the hold plane F1 at the irradiation position PT may fall in the range of 0° to 45°, the plane including the moving direction of the target member TM on the hold plane F1 at the irradiation position PT and a normal line to the hold plane F1. This configuration is another example of optional positional arrangements of the collector mirror 251 in the light source apparatus 1 according to the first embodiment. With this configuration, it is possible to prevent the generated light L0 from being blocked by the target holding unit 100. This advantageous effect is more prominent particularly in the situation where the target holding unit 100 includes an opposing wall 133, like in the light source apparatus 2 according to the second embodiment explained later.

### Modified Example 1-1

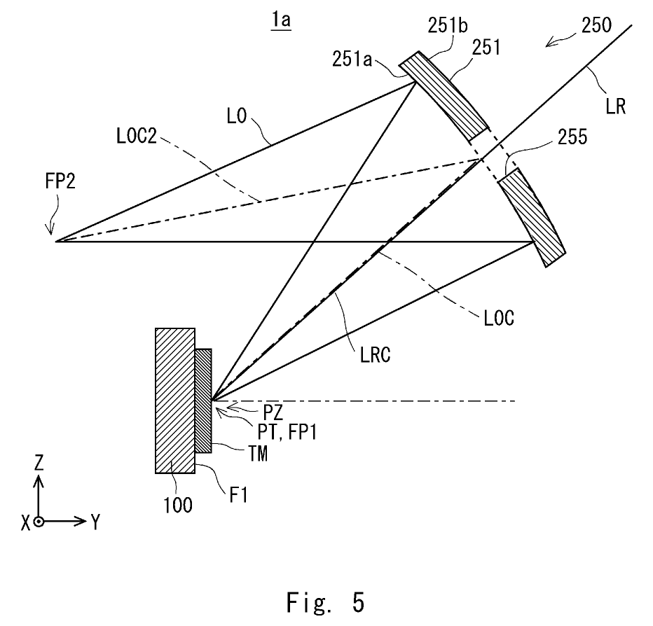

FIG. 5 is a cross-sectional view showing an example of a light source apparatus 1a according to a first modified example of the first embodiment. As shown in FIG. 5, in the light source apparatus 1a, the direction of the optical axis LRC of the excitation light LR may coincide with the direction of the optical axis L0C of the generated light L0 traveling from the plasma PZ toward the collector mirror 251. In other words, the optical axis LRC of the excitation light LR to be radiated onto the target member TM and the optical axis L0C of the generated light L0 traveling from the plasma PZ toward the mirror have regions that substantially coincide with each other. In this situation, coinciding denotes not only the situation in which the direction of the optical axis LRC strictly coincides with the direction of the optical axis L0C, but is also used in a sense including a measurement error of a measurement apparatus for measuring the direction of the optical axis LRC and the direction of the optical axis L0C, as well as a tilt that may be caused by a manufacture error occurring during the manufacture of the light source apparatus 1a. Further, the term coinciding is used in a sense including the situation where a formed angle is small enough (e.g., 5 degrees or smaller) to be regarded as being equal in terms of designs. Coinciding in this sense may be expressed as substantially coinciding. Also, substantially coinciding may simply be expressed as coinciding.

For example, it is also conceivable to form the through hole 255 at the center of the reflection surface 251a so as to make the direction of the optical axis LRC coincide with the direction of the optical axis L0C. With this configuration, it is possible to suppress an impact of a positional change of the plasma PZ which may be caused by a change of the direction of the optical axis LRC of the excitation light LR at the irradiation position PT (the first focused point FP1).

### Modified Example 1-2

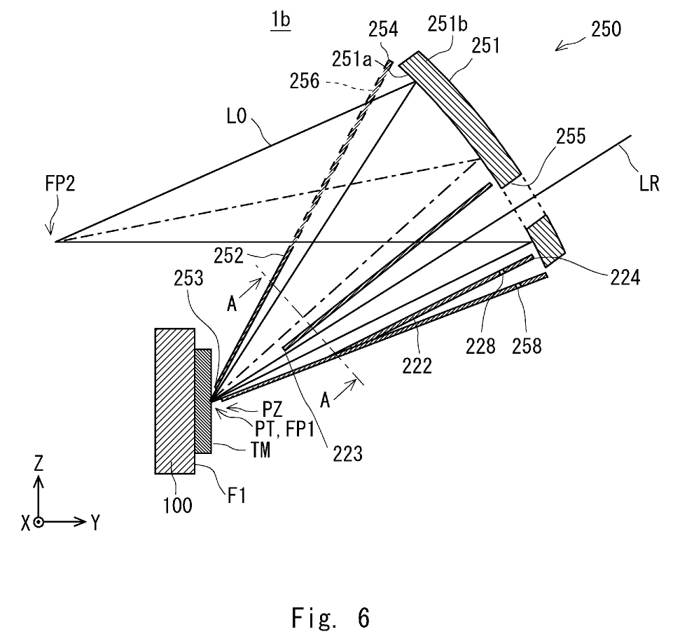

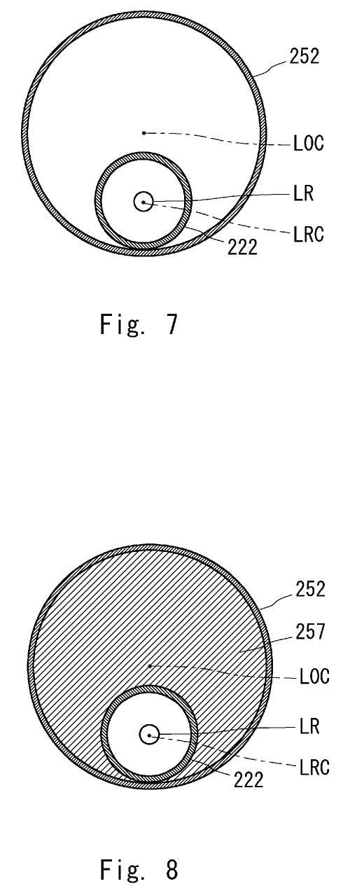

FIG. 6 is a cross-sectional view showing an example of a light source apparatus 1b according to a second modified example of the first embodiment. FIG. 7 is a cross-sectional view showing examples of an optical path cover 222 and an optical path cover 252 in the light source apparatus 1b according to the second modified example of the first embodiment, showing a cross-section taken at line A-A in FIG. 6. As shown in FIGS. 6 and 7, the light source apparatus 1b further includes the optical path cover 222 and the optical path cover 252.

The optical path cover 222 includes a part positioned between the target member TM and the collector mirror 251. In other words, the optical path cover 222 may include a part positioned on the reflection surface 251a side of the collector mirror 251. The optical path cover 222 is positioned so that one end 223 thereof opposes the target member TM, while the other end 224 opposes the collector mirror 251. The optical path cover 222 is not excluded from including a part positioned on the opposite surface 251b side of the collector mirror 251. For example, the optical path cover 222 may include a region formed inside the through hole 255.

The optical path cover 222 may have a cone shape or a truncated cone shape that is hollow inside. More specifically, while the optical path cover 222 has a tubular shape having the one end 223 open and also having the other end 224 open, the opening diameter at the other end 224 may be larger than the opening diameter at the one end 223, so that the diameter of the tubular shape increases from the opening at the one end 223 toward the opening at the other end 224. Further, the optical path cover 222 may include a part in which the diameter does not gradually increase from the opening at the one end 223 toward the opening at the other end 224. More specifically, as long as the optical path cover 222 has a tubular shape having the one end 223 open and also having the other end 224 open, and also, the opening diameter at the other end 224 of the tubular shape is larger than the opening diameter at the one end 223 thereof, the optical path cover 222 may have a part shaped other than a cone shape or a truncated cone shape.

The optical path cover 222 covers at least a portion of an optical path of the excitation light LR. For example, the optical path cover 222 covers at least a portion of the optical path of the excitation light LR positioned between the target member TM and the collector mirror 251. The optical path cover 222 has an inner circumferential surface and an outer circumferential surface. The excitation light LR passes through a region surrounded by the inner circumferential surface of the optical path cover 222. The optical path cover 222 may be referred to as an excitation light cover or an excitation light cone.

The optical path cover 222 may have, in the lateral face thereof, an introduction port 228 for introducing a gas. The gas may be introduced to the inside of the optical path cover 222 through the introduction port 228. It is desirable to provide the introduction port 228 on the other end 224 side. The gas introduced through the introduction port 228 passes through the inside of the optical path cover 222 and jets out from the one end 223. With this configuration, it is possible to prevent debris of the target member TM from adhering to component parts (optical members or the like) such as the collector mirror 251. A gas may be introduced through the introduction port 228 to the inside of the optical path cover 252 (explained later), which is on the outside of the optical path cover 222. It is desirable to provide the introduction port 228 on the other end 224 side. The gas introduced through the introduction port 228 passes through the inside of the optical path cover 252 and jets out from one end 253. With this configuration, it is possible to prevent debris of the target member TM from adhering to component parts (optical members or the like) such as the collector mirror 251.

The optical path cover 252 incudes a part positioned between the target member TM and the collector mirror 251. In an example, the optical path cover 252 may cover the periphery of the collector mirror 251 so as to include the collector mirror 251 on the inside thereof. The one end 253 of the optical path cover 252 may oppose the target member TM, whereas the other end 254 may be positioned in the vicinity of the collector mirror 251. The optical path cover 252 is not excluded from including a part positioned on the opposite surface 251b side of the collector mirror 251.

The optical path cover 252 may have a cone shape or a truncated cone shape that is hollow inside. More specifically, while the optical path cover 252 has a tubular shape having the one end 253 open and also having the other end 254 open, the opening diameter at the other end 254 may be larger than the opening diameter at the one end 253, so that the diameter of the tubular shape increases from the opening at the one end 253 toward the opening at the other end 254. Further, the optical path cover 252 may include a part in which the diameter does not gradually increase from the opening at the one end 253 toward the opening at the other end 254. More specifically, as long as the optical path cover 252 has a tubular shape having the one end 253 open and also having the other end 254 open, and also, the opening diameter at the other end 254 of the tubular shape is larger than the opening diameter at the one end 253 thereof, the optical path cover 252 may have a part shaped other than a cone shape or a truncated cone shape.

The optical path cover 252 covers at least a portion of an optical path of the generated light L0. For example, the optical path cover 252 covers at least a portion of the optical path of the generated light L0 positioned between the target member TM and the collector mirror 251. The optical path cover 252 has an inner circumferential surface and an outer circumferential surface. The generated light L0 passes through a region surrounded by the inner circumferential surface of the optical path cover 252. A portion of the optical path cover 252 may have formed therein a hole 256 for extracting the generated light L0 to the outside of the light source apparatus 1b. The generated light L0 reflected on the reflection surface 251a is extracted to the outside through the hole 256.

The optical path cover 252 may have, in the lateral face thereof, an introduction port 258 for introducing a gas. The gas may be introduced to the inside of the optical path cover 252 through the introduction port 258. It is desirable to provide the introduction port 258 on the other end 254 side. The gas introduced through the introduction port 258 passes through the inside of the optical path cover 252 and jets out from the one end 253. With this configuration, it is possible to prevent debris of the target member TM from adhering to component parts (optical members or the like) such as the collector mirror 251.

A portion of the outer circumferential surface of the optical path cover 222 may be in contact with a portion of the inner circumferential surface of the optical path cover 252 (for example, see FIG. 7). For example, an outer circumferential surface part of the optical path cover 222 positioned on the one end 223 side may be in contact with the inner circumferential surface of the optical path cover 252. The optical path cover 252 may be referred to as a generated light cover or a generated light cone.

FIG. 8 is a cross-sectional view showing examples of the optical path cover 222, the optical path cover 252, and a filter 257 in the light source apparatus 1b according to the second modified example of the first embodiment. As shown in FIG. 8, the light source apparatus 1b may further include the filter 257. The filter 257 is in contact with the outer circumferential surface of the optical path cover 222 covering at least a portion of the optical path of the excitation light LR and with the inner circumferential surface of the optical path cover 252 covering at least a portion of the optical path of the generated light L0. With this configuration, in the situation where the optical path cover 222 covering at least a portion of the optical path of the excitation light LR is provided in a region positioned on the inner circumference side of the optical path cover 252 covering at least a portion of the optical path of the generated light L0, it is possible to eliminate the need to provide an attachment mechanism such as a bridge used for attaching the filter 257, when disposing the filter 257 on the optical path of the generated light L0. Thus, it is possible to prevent the generated light L0 from being blocked by the attachment mechanism.

The filter 257 is configured to transmit the generated light L0, while preventing debris resulting from the plasma PZ from adhering to the collector mirror 251. Further, the filter 257 may include a function of a bandpass filter configured to selectively transmit specific generated light L0 such as EUV light. In the situation where the filter 257 is provided, it is desirable to form the introduction port 258 in the vicinity of the filter 257 so as to be positioned on the one end 253 side relative to the position of the filter 257. With this configuration, it is possible to prevent debris of the target member TM from adhering to the filter 257. Further, in the situation where a portion of the optical path cover 252 has formed therein the hole 256 for extracting the generated light L0 to the outside of the light source apparatus 1b, it is desirable to provide the filter 257 on the one end 253 side relative to the hole 256.

Next, advantageous effects of the present embodiment will be explained. The light source apparatuses 1, 1a, and 1b of the present embodiment are configured to radiate the excitation light LR through the missing part (the through hole 255, the missing area 255a, etc.) of the collector mirror 251, onto the target member TM held by the target holding unit 100. With this configuration, because it is possible to cause the optical path of the excitation light LR to overlap a portion of the optical path of the generated light L0, it is possible to keep the light source apparatuses 1, 1a, and 1b compact. In other words, even when the collector mirror 251 is enlarged or an attachment posture of the collector mirror 251 is changed, for example, for the purpose of increasing the amount of the generated light L0 to be extracted, it is possible to secure the optical path of the excitation light LR toward the target member TM. Consequently, it is possible to provide the light source apparatuses 1, 1a, and 1b capable of striking a balance between the layout and performance.

Because the light source apparatus 1b has the optical path covers 222 and 252, it is possible to prevent the debris resulting from the plasma PZ from adhering to component parts such as the collector mirror 251. It is also conceivable to provide the optical path cover 222 and the optical path cover 252 with the introduction port 228 and the introduction port 258, so as to cause the gas to flow from the other end 224 side and the other end 254 side to the one end 223 side and the one end 253 side. With this configuration, it is possible to further prevent the debris from adhering to the component parts such as the collector mirror 251. It is also conceivable to use the missing part such as the through hole 255 as a gas introduction port or a gas path. With this configuration, because it is possible to dispose the gas path on the opposite surface 251b side of the collector mirror 251, it is possible to keep the light source apparatus 1b compact.

The direction of the optical axis LRC of the excitation light LR may be configured to be different from the direction of the optical axis L0C of the generated light L0 traveling from the plasma PZ toward the collector mirror 251. With this configuration, it is possible to increase the NA of the collector mirror 251 in various layouts.

### Second Embodiment

Next, the light source apparatus 2 according to the second embodiment will be explained. In the present embodiment, the target holding unit 100 includes, in an example, a container such as a crucible. The target holding unit 100 is configured to hold the target member TM being a liquid.

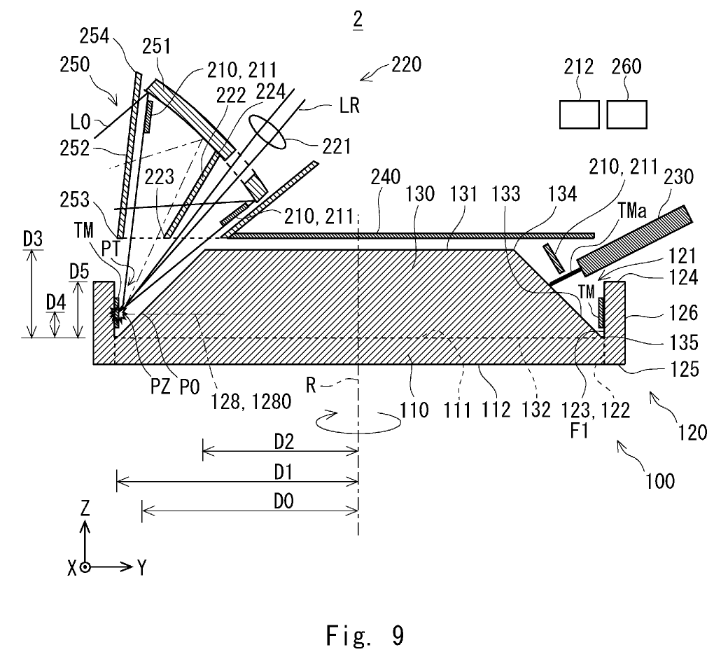

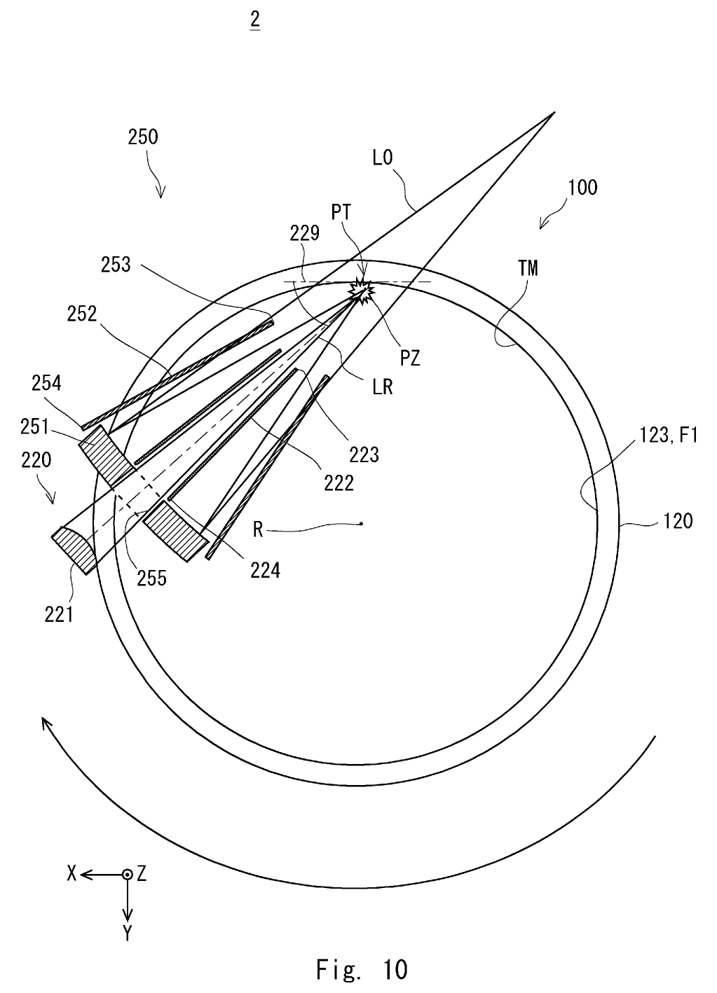

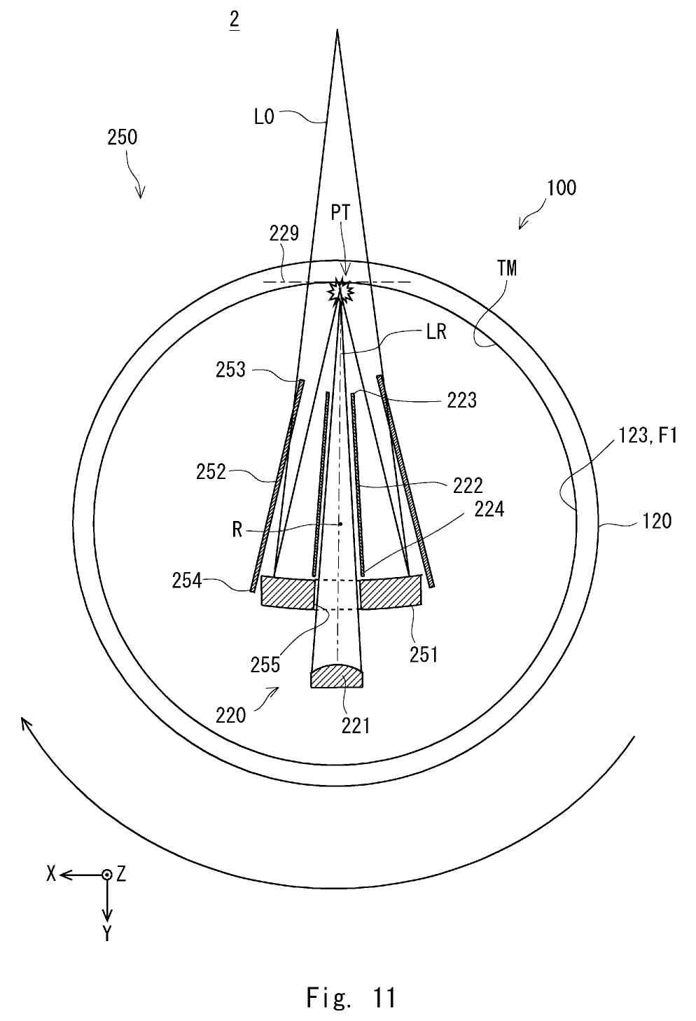

FIG. 9 is a cross-sectional view showing an example of the light source apparatus 2 according to the second embodiment. FIG. 10 is a plan view showing examples of the target holding unit 100; a generation unit 220, and the output optical system 250 in the light source apparatus 2 according to the second embodiment. In FIGS. 9 and 10, a number of members are omitted so as to prevent the drawings from becoming too complicated. Further, a number of reference characters may also be omitted. The same applies to the drawings referenced hereinafter.

As shown in FIGS. 9 and 10, the light source apparatus 2 may further include, in addition to the target holding unit 100 and the output optical system 250, an acquisition unit 210, the generation unit 220, a supply unit 230, a cover part 240, and a control unit 260. The target holding unit 100 includes the container such as a crucible configured to rotate around a rotation axis R. The target holding unit 100 is capable, on the inside thereof, of melting a metal to serve as the target member TM.

In the present embodiment, the rotation axis R of the target holding unit 100 will be defined as Z axis directions. In the present embodiment, the Z axis directions are defined as vertical directions, i.e., the gravity directions. Further, the upward direction of the gravity directions will be defined as a +Z axis direction, whereas the downward direction of the gravity directions will be defined as a -Z axis direction. Conversely, as explained later, the downward direction of the gravity directions may be defined as a +Z axis direction, whereas the upward direction of the gravity directions may be defined as a -Z axis direction. In another example, horizontal directions orthogonal to the gravity directions or directions tilted from the gravity directions may be defined as Z axis directions.

As a result of the target holding unit 100 rotating around the rotation axis R, a centrifugal force uniformly acts on the target member TM held by the target holding unit 100. Thus, it is possible to make the thickness of the target member TM uniform and to thus stabilize the generated light L0 extracted from the light source apparatus 2. The target holding unit 100 may include a bottom part 110, a cylindrical part 120, and an opposing part 130.

The bottom part 110 is positioned on the -Z axis direction side of the opposing part 130. Thus, the opposing part 130 is positioned on the +Z axis direction side of the bottom part 110. The bottom part 110 and the opposing part 130 are disposed on the inside surrounded by the cylindrical part 120. The cylindrical part 120 is positioned so as to surround the rotation axis R. In the present embodiment, the bottom part 110 is positioned below the opposing part 130 in the gravity directions. Accordingly, the opposing part 130 is positioned above the bottom part 110 in the gravity directions.

For example, the bottom part 110 is a disc-shaped member and is connected to the cylindrical part 120 so as to be contiguous with the cylindrical part 120. In the situation where the opposing part 130 is hollow inside, the bottom part 110 may be an annular member. The central axis of the bottom part 110 having a disc shape or an annular shape may coincide with the rotation axis R. The bottom part 110 may have, as opposing plate surfaces, a first surface 111 and a second surface 112. The first surface 111 is facing the +Z axis direction side, whereas the second surface 112 is facing the -Z axis direction side. In the present embodiment, the first surface 111 is facing upward in the gravity directions, whereas the second surface 112 is facing downward in the gravity directions. The opposing part 130 is positioned so as to be in contact with the first surface 111 of the bottom part 110. In an example, the bottom part 110 and the opposing part 130 may integrally be formed. In that situation, the opposing part 130 is formed to be contiguous with the first surface 111 of the bottom part 110. In that situation, the first surface 111 is an imaginary plane.

For example, the cylindrical part 120 includes a member having a cylindrical shape. The central axis of the cylindrical part 120 having a cylindrical shape may coincide with the rotation axis R. One of the openings 121 of the cylindrical part 120 is facing the +Z axis direction side. The other opening 122 of the cylindrical part 120 is facing the -Z axis direction side. In the present embodiment, the opening 121 is facing upward, whereas the opening 122 is facing downward. The opening 122 is connected so as to be contiguous with the bottom part 110. Accordingly, the opening 122 of the cylindrical part 120 is closed by the bottom part 110. For example, as a result of the bottom part 110 disposed inside the opening 122, the opening 122 is closed by the bottom part 110.

As explained above, the cylindrical part 120 is open on one side, while the other side is contiguous with the bottom part 110. More specifically, the cylindrical part 120 is configured so that the end on the +Z axis direction side is open while the end on the -Z axis direction side is contiguous with the bottom part 110. In the present embodiment, the direction of the opening 121 at which the cylindrical part 120 is open is the upward direction of the gravity directions. As explained later, the direction of the opening 121 at which the cylindrical part 120 is open may be the downward direction of the gravity directions. In other examples, the direction of the opening 121 at which the cylindrical part 120 is open may be orthogonal to the gravity directions or may be tilted with respect to the gravity directions.

Alternatively, the bottom part 110 and the cylindrical part 120 may integrally be formed. In that situation, the bottom part 110 is formed so as to be contiguous with the opening 122 of the cylindrical part 120. The opening 122 shall be an imaginary opening.

A part of the cylindrical part 120 positioned on the opening 121 side will be referred to as an opening side cylindrical part 124. A part of the cylindrical part 120 positioned on the bottom part 110 side will be referred to as a bottom part cylindrical part 125. A part of the cylindrical part 120 positioned between the opening side cylindrical part 124 and the bottom part cylindrical part 125 will be referred to as a main body part 126. Thus, the cylindrical part 120 includes the main body part 126, the opening side cylindrical part 124, and the bottom part cylindrical part 125. The opening side cylindrical part 124 is a part of the cylindrical part 120 positioned on the +Z axis direction side. The opening side cylindrical part 124 is positioned on the +Z axis direction side of the main body part 126. The bottom part cylindrical part 125 is a part of the cylindrical part 120 positioned on the -Z axis direction side. The bottom part cylindrical part 125 is positioned on the -Z axis direction side of the main body part 126.

The inner circumferential surface of the cylindrical part 120 will be referred to as an inside wall 123. The inside wall 123 is formed so as to surround the rotation axis R. Thus, the rotation axis R is positioned so as to be surrounded by the inside wall 123. The inside wall 123 is configured to hold the target member TM that generates the plasma PZ by being irradiated with the excitation light LR. Accordingly, in this situation, the inside wall 123 includes the hold plane F1.

For example, the opposing part 130 includes a member having a truncated cone shape. The opposing part 130 having a truncated cone shape may have a first face 131 and a second face 132 as a ceiling face and a bottom face opposing each other in the Z axis directions. The first face 131 is facing the +Z axis direction side. The second face 132 is facing the -Z axis direction side. In the present embodiment, the first face 131 is facing upward in the gravity directions, whereas the second face 132 is facing downward in the gravity directions. The first face 131 of the opposing part 130 is smaller than the second face 132.

The central axis of the opposing part 130 having the truncated cone shape may coincide with the rotation axis R. The bottom part 110 is connected to the second face 132 of the opposing part 130. As mentioned earlier, the bottom part 110 and the opposing part 130 may integrally be formed. In that situation, the second face 132 is an imaginary plane. The lateral face of the opposing part 130 will be referred to as the opposing wall 133.

The opposing wall 133 is surrounded by the cylindrical part 120. The opposing wall 133 is positioned on the rotation axis R side relative to the cylindrical part 120. The opposing wall 133 opposes the inside wall 123 of the cylindrical part 120. The opposing wall 133 may be formed over the entire circumference along the rotating direction around the rotation axis R. An end part of the opposing wall 133 positioned on the opening 121 side will be referred to as an opening side end part 134. The opening side end part 134 is an end part of the opposing wall 133 positioned on the +Z axis direction side. An end part of the opposing wall 133 positioned on the bottom part 110 side will be referred to as a bottom part side end part 135. The bottom part side end part 135 is an end part of the opposing wall 133 positioned on the -Z axis direction side. Thus, the opening side end part 134 is the end part on the opposite side from the bottom part side end part 135.

The distance from the opposing wall 133 to the rotation axis R may gradually decrease, starting from the bottom part side end part 135 toward the opening side end part 134. The intersection point of the opposing wall 133 and a normal line 1280 being orthogonal to the rotation axis R and passing through the irradiation position PT will be defined as an intersection point P0. In that situation, the distance from the opposing wall 133 to the rotation axis R may gradually decrease, starting from the bottom part side end part 135 toward the intersection point P0. In other words, between the intersection point P0 of the opposing wall 133 and the bottom part side end part 135, a region may be included in which the distance from the rotation axis R is longer than a distance D0 from the rotation axis R to the intersection point P0. Further, the distance from the opposing wall 133 to the rotation axis R may gradually decrease, starting from the intersection point P0 toward the opening side end part 134. In other words, between the intersection point P0 of the opposing wall 133 and the opening side end part 134, a region may be included in which the distance from the rotation axis R is shorter than the distance D0 from the rotation axis R to the intersection point P0.

The distance from the opposing wall 133 to the rotation axis R may gradually decrease, starting from the bottom part side end part 135 toward the opening side end part 134. Further, the distance from the opposing wall 133 to the rotation axis R may gradually decrease, starting from the bottom part side end part 135 toward the vicinity of the opening side end part 134. Further, the opening side end part 134 may have a protruding part. In that situation, the vicinity of the opening side end part 134 may denote a position on the opposing wall 133 corresponding to the protruding part jutting out toward the opposing wall 133. As described herein, the opposing part 130 may have the part that partially protrudes from the truncated cone shape.

The acquisition unit 210 is configured to acquire information about the inside wall 123 of the target holding unit 100. The information about the inside wall 123 will be referred to as state information. In addition, the acquisition unit 210 is configured to acquire information about a bright point position of the plasma PZ. The information about the bright point position will be referred to as bright point information. The generated light L0 may include EUV light and may include visible light. Further, the generated light L0 may include light having a wavelength other than those of EUV light and visible light. From within the generated light L0, the acquisition unit 210 may acquire at least one of the state information and the bright point information from the EUV light, for example. Alternatively, from within the generated light L0, the acquisition unit 210 may acquire at least one of the state information and the bright point information from the visible light, for example.

The acquisition unit 210 may include a sensor 211 and a processing unit 212. The sensor 211 may include a camera and may include a position sensor. The camera may be configured to capture a still image or to capture a moving image. The sensor 211 and the processing unit 212 are connected together in a state in which information can be transferred by a communication line including a wired or wireless scheme. The acquisition unit 210 may include a single sensor 211 or may include a plurality of sensors 211. The acquisition unit 210 may acquire the state information and the bright point information by employing mutually the same sensor 211. Alternatively, the acquisition unit 210 may acquire the state information and the bright point information by employing mutually-different sensors 211.

As the state information of the inside wall 123 of the target holding unit 100, the acquisition unit 210 may acquire image information of the inside wall 123 captured by the camera. The acquisition unit 210 may acquire the amount of the target member TM, based on a region of the inside wall 123 occupied by the target member TM as indicated in the acquired state information (i.e., as identified based on the state information). The processing unit 212 is configured to acquire the amount of the target member TM, based on at least one of the width and the area of the region of the inside wall 123 occupied by the target member TM as indicated in the image information. The width and the area of the region of the inside wall 123 occupied by the target member TM may be acquired based on the region of a part identified as the target member TM in the captured image.

Based on the acquired bright point information, the acquisition unit 210 may acquire the irradiation position PT. For example, of the generated light L0 generated from the plasma PZ, the sensor 211 may be disposed in at least one selected from between a position for detecting the generated light L0 passing through the vicinity of an end part of the opening side cylindrical part 124 and a position for detecting the generated light L0 passing through the vicinity of the opening side end part 134. With this positional arrangement, in the situation where the generated light L0 generated from the plasma PZ reaches the sensor 211, it is possible to determine that the bright point position is in a prescribed position. On the contrary, in the situation where the generated light L0 generated from the plasma PZ does not reach the sensor 211 because of being blocked by the opening side cylindrical part 124 or the opening side end part 134, it is possible to determine that the bright point position deviates from the prescribed position.

Further, the acquisition unit 210 may acquire the state information and the bright point information of the inside wall 123 via the missing part (the through hole 255 or the like) of the collector mirror 251. For example, the acquisition unit 210 may acquire the state information and the bright point information from the generated light L0 passing through the through hole 255. With this configuration, for the purpose of acquiring the state information and the bright point information, it is possible to effectively utilize certain generated light L0 that is not used by an optical apparatus, such as the generated light L0 that is not reflected by the reflection surface 251a and that enters the through hole 255.

The acquisition unit 210 may predict the amount of the target member TM, based on the region of the inside wall 123 occupied by the target member TM as indicated in the acquired state information (i.e., as identified based on the state information). In other words, the acquisition unit 210 may acquire the predicted amount of the target member TM. For example, the acquisition unit 210 may acquire supply information about the target member TM supplied by the supply unit 230, directly from the supply unit 230 or indirectly via the control unit 260 or the like. The acquisition unit 210 may predict the amount of the target member TM based on the supply information and the state information.

Further, the acquisition unit 210 may predict the bright point position and the irradiation position PT, based on the bright point position indicated in the acquired bright point information (i.e., identified based on the bright point information). In other words, the acquisition unit 210 may acquire the bright point position and the irradiation position PT that are predicted. For example, the acquisition unit 210 may acquire the supply information about the target member TM supplied by the supply unit 230, directly from the supply unit 230 or indirectly via the control unit 260 or the like. The acquisition unit 210 may predict the bright point position and the irradiation position PT based on the supply information and the bright point information.

The acquisition unit 210 may acquire the state information and the bright point information from detection means such as a position sensor other than the camera. For example, the acquisition unit 210 may acquire the state information and the bright point information from the position of the target member TM detected by the position sensor. The position sensor is configured to detect the position of an end part of the target member TM. In this manner, the position sensor may detect at least one of the width and the area of the region of the inside wall 123 occupied by the target member TM. As another example, from the position of the bright point of the plasma PZ, the position sensor may detect the position at which the plasma PZ is generated and the irradiation position PT.

The position sensor may include, for example, a displacement meter, a high-speed camera, a low-speed camera, a split Photo Diode (PD), and/or a Time Delay Integration (TDI) camera. Further, the position sensor may be configured to measure a surface position one-dimensionally, two-dimensionally, or three-dimensionally or may combine any of these. As explained herein, the acquisition unit 210 may include a displacement meter configured to output a displacement amount of the surface position of the target member TM covering the inside wall 123. Based on the image information and the displacement amount, the acquisition unit 210 may be configured to acquire the amount of the target member TM and the bright point position.

Further, the acquisition unit 210 may use both the camera and the position sensor or the like. Regarding the camera and the position sensor or the like, the acquisition unit 210 may use one of the two for a supplemental application to the other. For example, regarding the camera and the position sensor or the like, the state information acquired by one of the two may be corrected by the other. The acquisition unit 210 may acquire or predict the amount of the target member TM, the bright point position, and the irradiation position PT, by combining the image information acquired from the camera with the position sensor or the like.

In addition to the optical path cover 222 described above, the generation unit 220 may include an optical member 221 such as a lens and a mirror or the like. The optical member 221 and the optical path cover 222 may be positioned on the +Z axis direction side of the target holding unit 100. The optical member 221 is configured to condense the excitation light LR on the target member TM. For example, by condensing laser light on the target member TM as the excitation light LR, the generation unit 220 is configured to excite the target member TM. The generation unit 220 is configured to cause the target member TM to be irradiated so that the excitation light LR has a component in the -Z axis direction. In the present embodiment, the generation unit 220 causes the target member TM to be irradiated so that the excitation light LR has a downward component in the gravity directions. The generation unit 220 causes the plasma PZ to be formed, by irradiating the target member TM with the excitation light LR. In this manner, the generation unit 220 generates the generated light L0 from the formed plasma PZ.

As long as the optical member 221 of the generation unit 220 is a member configured to irradiate the target member TM with the excitation light LR, the optical member 221 is not limited to being the condenser lens and the mirror and may include a laser generator configured to generate the excitation light LR. In other words, the light source apparatus 2 may include the laser generator or the like configured to generate the excitation light LR. As another example, the light source apparatus 2 may be configured to introduce, to the light source apparatus 2, the excitation light LR from the laser generator installed apart from the light source apparatus 2 on the outside of the light source apparatus 2. The excitation light LR may be radiated onto the target member TM as being controlled by the control unit 260 to oscillate and to stop.

The one end 223 of the optical path cover 222 may be connected to the cover part 240. The one end 223 of the optical path cover 222 may penetrate the cover part 240. The other end 224 of the optical path cover 222 is positioned on the +Z axis direction side relative to the cover part 240. As described herein, the optical path cover 222 may be attached to the cover part 240. In the present embodiment, the optical path cover 222 is positioned above the target holding unit 100 in the gravity directions. In the gravity directions, the one end 223 is facing downward, whereas the other end 224 is facing upward. The optical path cover 222 may be divided into a plurality of segments. The optical path cover 222 may or may not include the optical member 221 on the inside thereof.

The optical path cover 222 may include a temperature adjustment mechanism such as a heater. By the temperature adjustment mechanism, the optical path cover 222 may be adjusted to have a temperature equal to or higher than the melting point of the target member TM. With this configuration, debris adhering to the optical path cover 222 may be melted so as to be returned to the target holding unit 100.

The supply unit 230 is configured to supply the target member TM to the target holding unit 100. The supply unit 230 may supply the target member TM being a solid to the target holding unit 100. The solid target member TM may have a linear shape. The target member TM having the linear shape may be held as being wound around a bobbin or the like. The supply unit 230 may supply the target member TM having the linear shape from the bobbin to the inside of the target holding unit 100.

The supply unit 230 may supply the target member TM that has been melted to the inside wall 123. The supply unit 230 may supply the target member TM that has been melted by using the opposing wall 133 to the inside wall 123. The supply unit 230 may bring a solid target member TMa into contact with the opposing wall 133, so as to be melted and supplied to the inside of the target holding unit 100. The target member TM melted by the opposing wall 133 reaches the inside wall 123 due to a centrifugal force. In this configuration, because the target member TM on the inside wall 123 does not need to come into contact with the solid target member TM, it is possible to prevent the temperature of the target member TM on the inside wall 123 from falling. In addition, it is possible to inhibit vibration of the liquid surface of the target member TM.

The cover part 240 is disposed so as to cover the target holding unit 100. For example, the cover part 240 is configured to cover the opening 121 of the target holding unit 100 positioned on the +Z axis direction side. In the present embodiment, the cover part 240 covers a position above the opening 121 in the gravity directions. The cover part 240 has formed therein an opening for allowing the excitation light LR to enter and an opening used for extracting EUV light LE.

The cover part 240 prevents the debris that may be scattered while the plasma PZ is being formed from being scattered inside the light source apparatus 2. The cover part 240 may be adjusted so as to have a temperature equal to or higher than the melting point of the target member TM. With this configuration, it is possible to melt again the debris adhering to the cover part 240, so as to be re-used as the target member TM.

As explained earlier, the output optical system 250 includes the collector mirror 251 and the optical path cover 252. The one end 253 of the optical path cover 252 may be connected to the cover part 240. The one end 253 of the optical path cover 252 may penetrate the cover part 240. The other end 254 of the optical path cover 252 is positioned on the +Z axis direction side relative to the cover part 240. As described herein, the optical path cover 252 may be attached to the cover part 240. In the present embodiment, the optical path cover 252 is positioned above the target holding unit 100 in the gravity directions. In the gravity directions, the one end 253 is facing downward, whereas the other end 254 is facing upward. The optical path cover 252 may be divided into a plurality of segments. The optical path cover 252 may or may not include the collector mirror 251 on the inside thereof.

The optical path cover 252 may include a temperature adjustment mechanism such as a heater. By the temperature adjustment mechanism, the optical path cover 252 may be adjusted to have a temperature equal to or higher than the melting point of the target member TM. With this configuration, debris adhering to the optical path cover 252 may be melted so as to be returned to the target holding unit 100.

The control unit 260 may be configured to control various members in the light source apparatus 2. The control unit 260 is connected to be able to transfer information to the various members in the light source apparatus 2, via a communication line including a wireless or wired scheme. For example, the control unit 260 is configured to analyze the state information and the bright point information acquired by the acquisition unit 210. Further, the control unit 260 is configured to analyze output information having been output by the output optical system 250 and including the intensity and an irradiation position or the like of the light L0 serving as illumination light or the like.

The control unit 260 is configured to control a formation state of the plasma PZ at the generation unit 220 including the intensity and the irradiation position PT or the like of the excitation light LR, based on the state information, the bright point information, and the output information or the like about the light L0 serving as illumination light or the like. Further, the control unit 260 is configured to control a supply state at the supply unit 230 including the temperature and a supply amount or the like of the target member TM, based on the state information, the bright point information, and the output information, or the like. Further, the control unit 260 is configured to control the temperature of the cover part 240 and the like, based on the state information, the bright point information, and the output information, or the like.

As shown in FIG. 10, as viewed from the direction of the rotation axis R, the excitation light LR may be radiated at an angle in the range of 0° to 60° with respect to a tangent line 229 at the irradiation position PT (which may be a straight line indicating the moving direction of the target member TM at the irradiation position PT) of the excitation light LR on the circumference at which the hold plane F1 intersects a plane orthogonal to the rotation axis R. Debris resulting when the plasma PZ is generated jet out while being centered on a direction orthogonal to the tangent line 229. Thus, the irradiation at the abovementioned angle makes it possible to prevent the debris from adhering to the collector mirror 251. This configuration means, in other words, that it is desirable, in the situation where the target member TM moves in conjunction with the moving of the hold plane F1, that the excitation light LR becomes incident at such an incident angle that the angle formed between the optical axis LRC of the excitation light LR when the optical axis LRC is projected on a plane and a line segment falls in the range of 0° to 60° degrees, the plane including the moving direction of the target member TM on the hold plane F1 at the irradiation position PT and the normal line to the hold plane F1, and the line segment being a segment of a straight line including the moving direction of the target member TM on the hold plane F1 at the irradiation position PT and being positioned on the upstream side relative to the irradiation position PT. This statement is similarly applicable not only to the situation where the target holding unit 100 is a container such as a crucible that allows the hold plane F1 to move as a result of rotation around the rotation axis R, but also to the situation where the target holding unit 100 is a cylindrical member such as a drum that allows the hold plane F1 to move as a result of rotation on the rotation axis R, and to the situation where the target holding unit 100 is a structure having a tape-like shape that allows the hold plane F1 to move as a result of a parallel displacement or the like.

FIG. 11 is another plan view showing the examples of the target holding unit 100, the generation unit 220, and the output optical system 250 in the light source apparatus 2 according to the second embodiment. As shown in FIG. 11, the excitation light LR may be radiated at an angle in the range of 80° to 90° with respect to the direction of the tangent line 229 at the irradiation position PT (which may be a straight line indicating the moving direction of the target member TM at the irradiation position PT) of the excitation light LR on the circumference at which the hold plane F1 intersects a plane orthogonal to the rotation axis R. In other words, the excitation light LR may be radiated from the direction substantially orthogonal to the hold plane F1 at the irradiation position PT. With this configuration, because it is possible to reduce the volume in which the plasma PZ is formed, this configuration is advantageous in exercising control to make the shape of the plasma PZ a desirable shape. This configuration means, in other words, that it is desirable, in the situation where the target member TM moves in conjunction with the moving of the hold plane F1, that the excitation light LR becomes incident at such an incident angle that the angle formed between the optical axis LRC of the excitation light LR when the optical axis LRC is projected on a plane and the normal line to the hold plane F1 at the irradiation position PT falls in the range of 0° to 10°, or optionally the formed angle is substantially 0°, the plane including the moving direction of the target member TM on the hold plane F1 at the irradiation position PT and the normal line to the hold plane F1. This statement is similarly applicable not only to the situation where the target holding unit 100 is a container such as a crucible that allows the hold plane F1 to move as a result of rotation around the rotation axis R, but also to the situation where the target holding unit 100 is a cylindrical member such as a drum that allows the hold plane F1 to move as a result of rotation on the rotation axis R, and to the situation where the target holding unit 100 is a structure having a tape-like shape that allows the hold plane F1 to move as a result of a parallel displacement or the like.

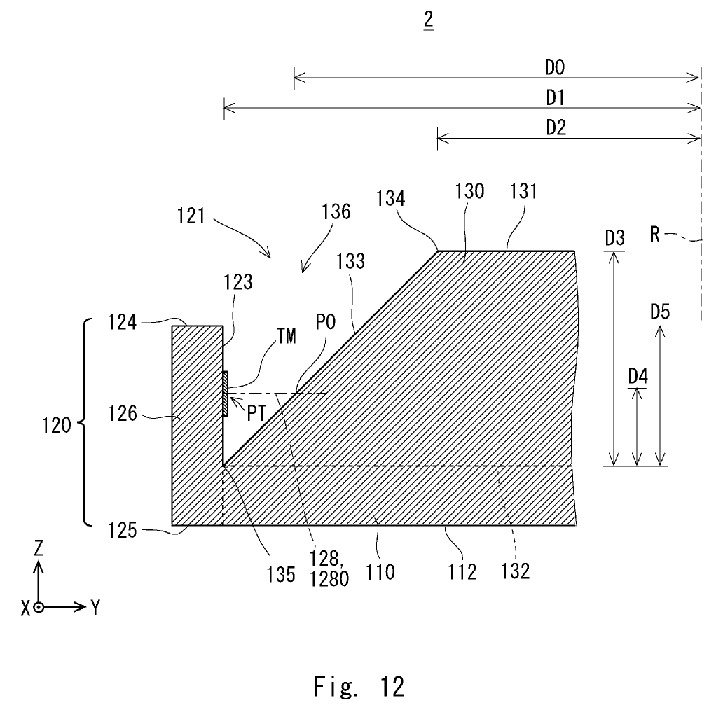

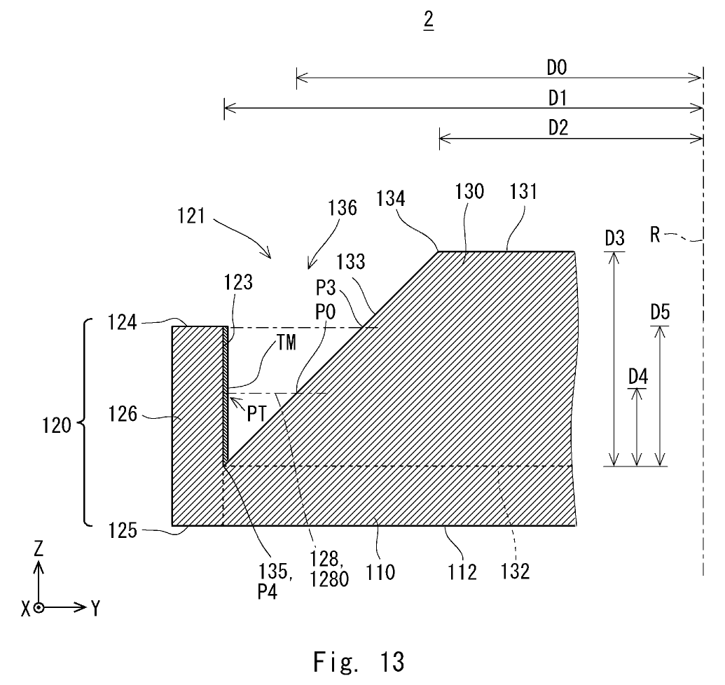

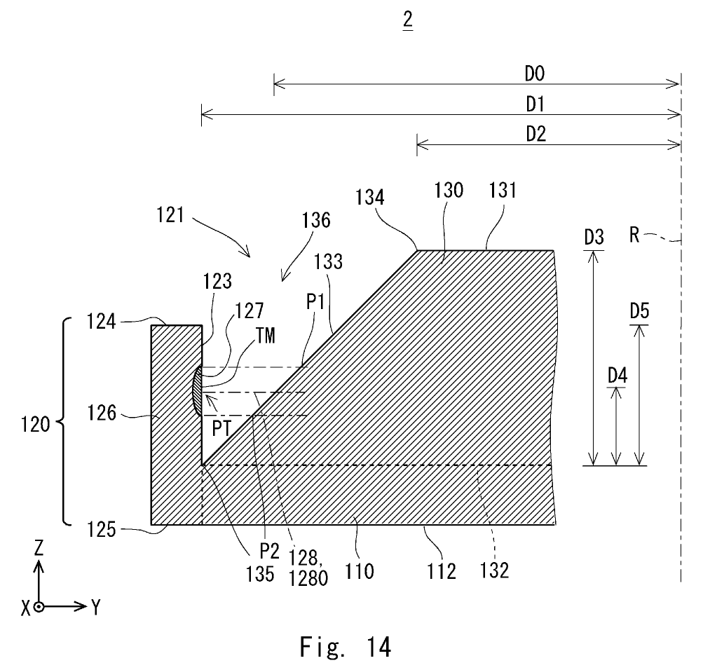

FIGS. 12 to 15 are cross-sectional views showing examples of the target member TM held by the inside wall 123 of the cylindrical part 120 of the target holding unit 100 in the light source apparatus 2 according to the second embodiment. As shown in FIG. 12, the target member TM is held by the inside wall 123 of the cylindrical part 120. The target member TM may be held by a partial region of the inside wall 123. As shown in FIG. 13, the target member TM may be held by the entire surface of the inside wall 123. As shown in FIG. 14, the inside wall 123 may have a recessed part formed along the inside wall 123. For example, the recessed part includes a groove 127. For example, the groove 127 may be formed along an intersection line of the inside wall 123 and a plane orthogonal to the rotation axis R. In other words, the groove 127 may include a part formed in the inside wall 123 along the rotating direction around the rotation axis R. In the inside wall 123, the groove 127 is recessed in the direction away from the rotation axis R.

In the situation where the inside wall 123 has the groove 127, the target member TM may be held by the groove 127. As a result of holding the target member TM in the groove 127, because it is possible to restrict moving of the target member TM in the Z axis directions, it is possible to prevent the liquid surface of the target member TM from being vibrated. In addition, because it is possible to restrict the amount of the target member TM to be within the groove 127, it is possible to reduce the amount of the target member TM being necessary. It should be noted that a portion of the target member TM held by the inside wall 123 may be positioned outside the groove 127.

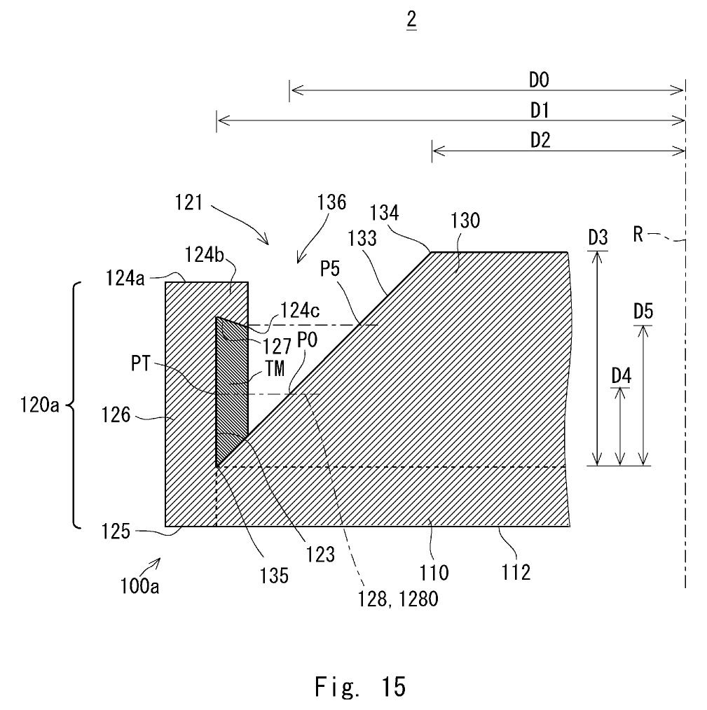

As shown in FIG. 15, a cylindrical part 120a of a target holding unit 100a may have an opening side cylindrical part 124a. The opening side cylindrical part 124a includes a protrusion part 124b protruding toward the rotation axis R side. The tip end of the protrusion part 124b on the rotation axis R side will be referred to as a tip end part 124c. In this configuration, the target member TM may be held so as to be surrounded by the protrusion part 124b. In other words, the groove 127 formed in the inside wall 123 may be formed as a result of the opening side cylindrical part 124a jutting out in the direction toward the rotation axis R. That is to say, the inside wall 123 may include a wall surface of the protrusion part 124b of the opening side cylindrical part 124a jutting out in the direction toward the rotation axis R. As explained herein, the inside wall 123 may include the groove 127 formed in the protrusion part 124b of the opening side cylindrical part 124a jutting out in the direction toward the rotation axis R.

As explained above, the inside wall 123 may have the groove 127 formed along the rotating direction around the rotation axis R. The irradiation position PT is included in the position at which the target member TM is held. In the situation where the groove 127 holds the target member TM, the irradiation position PT is included in the range of the groove 127 in the Z axis directions. Straight lines orthogonal to the rotation axis R will be referred to as normal lines. Among the normal lines, a normal line passing through the irradiation position PT will be assigned with a reference numeral and referred to as the normal line 1280. The opposing wall 133 of the opposing part 130 may be present, at least, so as to intersect a normal line passing through the end part of the groove 127 in the +Z axis direction and so as to intersect a normal line passing through the end part of the groove 127 in the -Z axis direction.

Further, in that situation, the opposing wall 133 may be formed in such a manner that the distance from the rotation axis R to an intersection point (called an intersection point P1; see FIG. 14) of the normal line passing through the end part of the groove 127 in the +Z axis direction and the opposing wall 133 is shorter than the distance from the rotation axis R to an intersection point (called an intersection point P2) of the normal line passing through the end part of the groove 127 in the -Z axis direction and the opposing wall 133. Furthermore, the opposing wall 133 may be formed in such a manner that the distance from the rotation axis R to the intersection point P2 may be shorter than a distance D1. In that situation, the opposing wall 133 may be formed in such a manner that the distance to the rotation axis R gradually decreases, in the range from the bottom part side end part 135 to the intersection point P0. Also, in addition, the opposing wall 133 may be formed in such a manner that the distance to the rotation axis R gradually decreases in the range from the intersection point P2 to the intersection point P1. Alternatively, the opposing wall 133 may be formed in such a manner that the distance to the rotation axis R gradually decreases in the range from the bottom part side end part 135 to the intersection point P1.

Further, the irradiation position PT may be included in the range of the target member TM on the inside wall 123 in the Z axis directions. In that situation, the opposing wall 133 may be present, at least, so as to intersect the normal line passing through the end part of the inside wall 123 in the +Z axis direction and to intersect the normal line passing through the end part of the inside wall 123 in the -Z axis direction. Further, in that situation, the opposing wall 133 may be formed in such a manner that the distance from the rotation axis R to an intersection point (called an intersection point P3; see FIG. 13) of the normal line passing through the end part of the inside wall 123 in the +Z axis direction and the opposing wall 133 is shorter than the distance from the rotation axis R to an intersection point (called an intersection point P4, but may be the same as the bottom part side end part 135) of the normal line passing through the end part of the inside wall 123 in the -Z axis direction and the opposing wall 133. In that situation, the opposing wall 133 may be formed in such a manner that the distance to the rotation axis R gradually decreases in the range from either the intersection point P4 or the bottom part side end part 135 to the intersection point P0. Furthermore, the opposing wall 133 may be formed in such a manner that the distance to the rotation axis R gradually decreases in the range from either the intersection point P4 or the bottom part side end part 135 to the intersection point P3.

Further, the irradiation position PT may be included in the range where the target member TM is held, within the range from the tip end part 124c of the protrusion part 124b of the opening side cylindrical part 124a to the bottom part 110. In that situation, the opposing wall 133 may be present so as to intersect a normal line passing through the tip end part 124c of the protrusion part 124b of the opening side cylindrical part 124. Further, in that situation, the opposing wall 133 may be formed in such a manner that the distance from the rotation axis R to an intersection point (called an intersection point P5; see FIG. 15) of the normal line passing through the tip end part 124c of the protrusion part 124b of the opening side cylindrical part 124 and the opposing wall 133 is shorter than the distance D1. In that situation, the opposing wall 133 may be formed in such a manner that the distance to the rotation axis R gradually decreases in the range from the bottom part side end part 135 to the intersection point P0. Furthermore, the opposing wall 133 may be formed in such a manner that the distance to the rotation axis R gradually decreases in the range from the bottom part side end part 135 to the intersection point P5.

Further, the Z axis direction position of the end part of the groove 127 in the -Z axis direction may coincide with the Z axis direction position of the first surface 111 of the bottom part 110 or may be at a position farther toward the +Z axis direction. This configuration can be guaranteed even in the situation where the groove 127 is formed by the protrusion part 124b of the opening side cylindrical part 124a jutting out in the direction toward the rotation axis R.

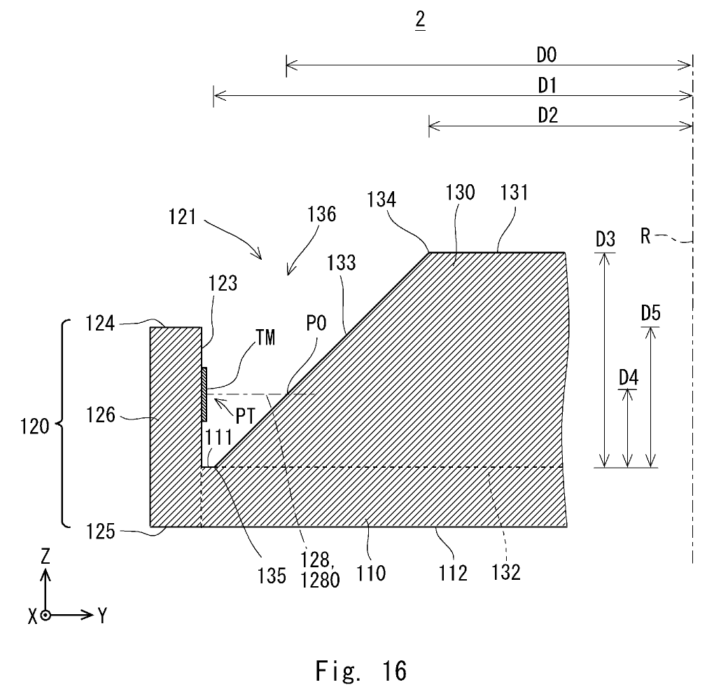

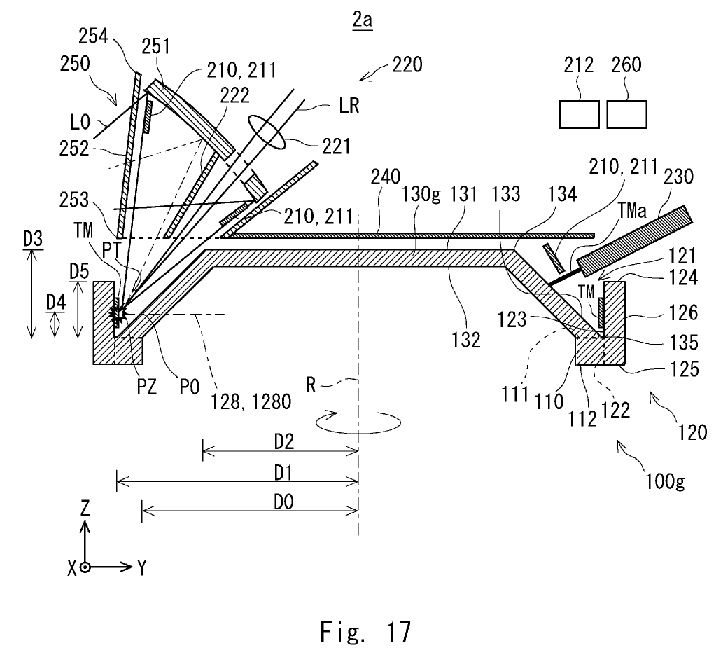

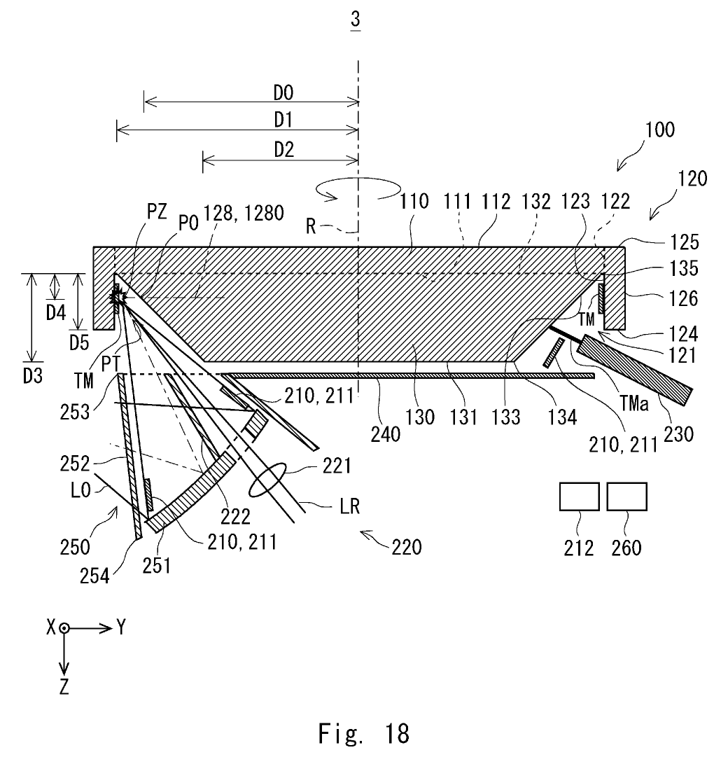

FIG. 16 is a cross-sectional view showing yet another example of the target member TM held by the inside wall 123 of the cylindrical part 120 of the target holding unit 100 in the light source apparatus 2 according to the second embodiment. The bottom part side end part 135 may be in contact with the cylindrical part 120. Alternatively, as shown in FIG. 16, the bottom part side end part 135 and the cylindrical part 120 may be positioned apart from each other. In other words, as seen from above, the first surface 111 of the bottom part 110 may be exposed between the bottom part side end part 135 and the cylindrical part 120.

In the present embodiment, the opening side end part 134 is the upper end of the opposing wall 133 in the gravity directions. The bottom part side end part 135 is the lower end of the opposing wall 133 in the gravity directions. The distance D1 from the rotation axis R to the bottom part side end part 135 is longer than a distance D2 from the rotation axis R to the opening side end part. Further, the distance D1 from the rotation axis R to the bottom part side end part 135 is longer than the distance D0 from the rotation axis R to the intersection point P0.

The opposing wall 133 intersects a normal line 128 to the surface of the target member TM at the irradiation position PT. While the target holding unit 100 is rotating at a high speed, the normal line 128 may be the same as the normal line 1280 in some situations. In those situations, the normal line 128 intersects the intersection point P0. When the target member TM is irradiated with the excitation light LR, debris will be scattered from the irradiation position PT of the target member TM. Even if the excitation light LR becomes incident to the surface of the target member TM at a tilted angle, the debris will be scattered while being centered on the direction of the normal line 128 normal to the surface of the target member TM at the irradiation position PT. Consequently, with the positioning in which the normal line 128 intersects the opposing wall 133, it is possible to receive the debris with the opposing wall 133 and to thus prevent the debris from being scattered into the light source apparatus 2.

A distance D3 from the bottom part 110 to the opening side end part 134 may be longer than a distance D4 from the bottom part 110 to the irradiation position PT. With this configuration, it is possible to enlarge the area of the opposing wall 133 for receiving the debris and to thus further prevent the debris from being scattered into the light source apparatus 2. The distance D3 from the bottom part 110 to the opening side end part 134 may be longer than a distance D5 from the bottom part 110 to the opening side cylindrical part 124. With this configuration, it is possible to guarantee the relationship of the distance D3 > the distance D4.

The space between the opening side end part 134 and the opening side cylindrical part 124 will be referred to as an irradiation space 136. The excitation light LR is radiated onto the irradiation position PT of the target member TM through the irradiation space 136. Further, the target member TM may be supplied to the target holding unit 100 through the irradiation space 136. Supplying the target member TM to the target holding unit 100 may be referred to as refilling. The opposing wall 133 may be set to have a temperature equal to or higher than the melting point of the target member TM. The opposing wall 133 may be set to have the temperature equal to or higher than the melting point of the target member TM, by radiant heat from the inside wall 123 and the target member TM held by the inside wall 123 or may be set to have the temperature equal to or higher than the melting point of the target member TM by a temperature adjustment mechanism such as a heater provided for the opposing part 130. The refilling of the target member TM may executed as a result of bringing the target member TM into contact with the opposing wall 133. The irradiation space 136 may be formed over the entire circumference along the rotating direction around the rotation axis R.

### Modified Example 2-1

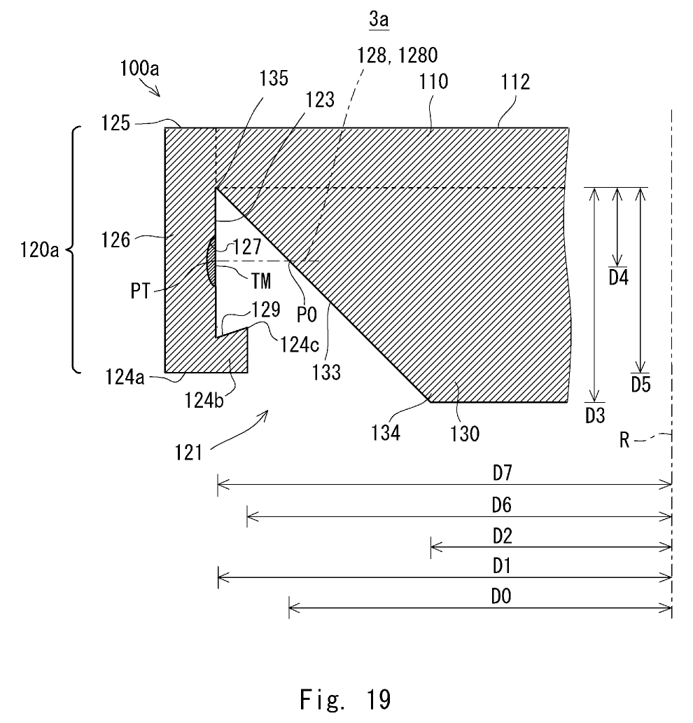

FIG. 17 is a cross-sectional view showing an example of a target holding unit 100g in a light source apparatus 2a according to a first modified example of the second embodiment. As shown in FIG. 17, in the target holding unit 100g according to the second modified example, the inside of an opposing part 130g may be "hollowed out", i.e., the opposing part 130g may include a cavity inside. In that situation, the opposing part 130g has a second face 132 on the inner surface of the interior. Except for being hollow inside and having the inner surface as the second face 132, the opposing part 130g has a configuration similar to that of the opposing part 130 described above.

Next, advantageous effects of the present embodiment will be explained. In the light source apparatuses 2 and 2a in the present embodiment, the target holding unit 100 has the opposing wall 133. Because the opposing wall 133 intersects the normal line 128 to the surface of the target member TM at the irradiation position PT, it is possible to prevent the debris resulting from the irradiation position PT from being scattered into the light source apparatuses 2 and 2a. Further, because the opposing wall 133 intersects the normal line 1280 being orthogonal to the rotation axis R and passing through the irradiation position PT, it is possible to prevent the debris resulting from the irradiation position PT from being scattered into the light source apparatuses 2 and 2a.

Further, because the distance D1 from the rotation axis R to the bottom part side end part 135 of the opposing wall 133 is longer than the distance D2 from the rotation axis R to the opening side end part 134 of the opposing wall 133 and is longer than the distance D0 from the rotation axis R to the intersection point P0 of the opposing wall 133, it is possible to return the debris scattered on the opposing wall 133 to the inside wall 123 with the centrifugal force. In addition, because it is possible to form the irradiation space 136, it is possible to cause the excitation light LR to go through the irradiation space 136 so as to be radiated onto the irradiation position PT. Further, it is possible to execute the refilling of the target member TM through the irradiation space 136. The range from the intersection point P0 of the opposing wall 133 to the opening side end part 134 includes a region in which the distance from the rotation axis R is shorter than the distance from the rotation axis R to the intersection point P0. Further, the distance from the opposing wall 133 to the rotation axis R gradually decreases, starting from the bottom part side end part 135 toward the opening side end part 134. With this configuration, it is possible to more smoothly return the debris scattered on the opposing wall 133 to the inside wall 123 with the centrifugal force.

By making the distance D3 from the bottom part 110 to the opening side end part 134 longer than the distance D4 from the bottom part 110 to the irradiation position PT, it is possible to further improve the catching of the debris by the opposing wall 133. By making the distance D3 from the bottom part 110 to the opening side end part 134 longer than the distance D5 from the bottom part 110 to the opening side cylindrical part 124, it is possible to further improve the catching of the debris by the opposing wall 133. In addition, it is possible to execute the refilling of the target member TM from the opposing wall 133 more smoothly. The configurations and advantageous effects of the second embodiment and the modified examples thereof other than those described above are included in the description of the first embodiment and the modified examples thereof.

### Third Embodiment

Next, a light source apparatus 3 according to a third embodiment will be explained. The light source apparatus 3 in the present embodiment is vertically inverted in the gravity directions, from the configuration of the light source apparatus 2 in the second embodiment. FIG. 18 is a cross-sectional view showing an example of the light source apparatus 3 according to the third embodiment. As shown in FIG. 18, the constituent elements of the light source apparatus 3 are opposite in terms of the upward direction and the downward direction in the gravity directions, as compared to the light source apparatus 2 in the second embodiment. In other words, in the present embodiment, the downward direction in the gravity directions will be defined as a +Z axis direction, whereas the upward direction in the gravity directions will be defined as a -Z axis direction. Accordingly, the layout positions of the constituent elements of the light source apparatus 3 in an XYZ orthogonal coordinate axes system are similar to those in the light source apparatus 2 in the second embodiment, except that the upward direction and the downward direction in the gravity directions are opposite.

For example, speaking of the bottom part 110, the configuration in the present embodiment in which the bottom part 110 is positioned on the -Z axis direction side of the opposing part 130 is similar to the configuration in the second embodiment; however, in the second embodiment, the bottom part 110 is positioned below the opposing part 130 in the gravity directions. In contrast, in the present embodiment, the bottom part 110 is positioned above the opposing part 130. Further, the configuration in the present embodiment in which the first surface 111 is facing the +Z axis direction side, whereas the second surface 112 is facing the -Z axis direction side is similar to the configuration in the second embodiment. However, in the second embodiment, the first surface 111 is facing upward, whereas the second surface 112 is facing downward in the gravity directions. In contrast, in the present embodiment, the first surface 111 is facing downward, whereas the second surface 112 is facing upward in the gravity directions.

Further, for example, speaking of the cylindrical part 120, in the present embodiment, the direction of the opening 121 at which the cylindrical part 120 is open is the +Z axis direction, which is the same as in the second embodiment. However, in the second embodiment, the direction of the opening 121 at which the cylindrical part 120 is open is the upward direction in the gravity directions. In contrast, in the present embodiment, the direction of the opening 121 at which the cylindrical part 120 is open is the downward direction in the gravity directions.

Further, for example, speaking of the opposing part 130, the configuration in the present embodiment in which the first face 131 of the opposing part 130 is facing the +Z axis direction side, whereas the second face 132 is facing the -Z axis direction side is similar to the configuration in the second embodiment. However, in the second embodiment, the first face 131 is facing upward, whereas the second face 132 is facing downward in the gravity directions. In contrast, in the present embodiment, the first face 131 is facing downward, whereas the second face 132 is facing upward in the gravity directions.

The layout positions in an XYZ orthogonal coordinate axes system of the constituent elements in the light source apparatus 3 other than the target holding unit 100 are also similar to those in the light source apparatus 2 in the second embodiment, except that the upward direction and the downward direction in the gravity directions are opposite.

In the second embodiment described above, the scattered debris may be routed back to the target holding unit 100. For example, debris that adhered to various members such as the opposing part 130, the cover part 240, the optical path cover 222, and the optical path cover 252, or the like, as well as debris scattered into the space above the target holding unit 100 in the gravity directions may return to the target holding unit 100 again due to gravity. In that situation, an adverse impact such as vibration may be imposed on the liquid surface of the target member TM held by the target holding unit 100.

In the present embodiment, due to gravity, the scattered debris fall below the target holding unit 100 in the gravity directions. As a result, it is possible to prevent the scattered debris from being routed back to the target holding unit 100.

### Modified Example 3-1

FIG. 19 is a cross-sectional view showing an example of the cylindrical part 120a of the target holding unit 100a in a light source apparatus 3a according to a first modified example of the third embodiment. As shown in FIG. 19, in the light source apparatus 3a in the present modified example, the cylindrical part 120a of the target holding unit 100a includes the opening side cylindrical part 124a. The opening side cylindrical part 124a includes the protrusion part 124b protruding toward the rotation axis R side relative to the main body part 126. Accordingly, because the opening side cylindrical part 124a protrudes toward the rotation axis R side, a distance D6 from the rotation axis R to the opening side cylindrical part 124a is shorter than a distance D7 from the rotation axis R to the inside wall 123. In the situation where the inside wall 123 does not have the groove 127 formed, the distance D7 from the rotation axis R to the inside wall 123 may be equal to the distance D1 from the rotation axis R to the bottom part side end part 135.

As explained earlier, in the situation where the inside wall 123 includes a wall surface of the protrusion part 124b of the opening side cylindrical part 124a jutting out in the direction toward the rotation axis R (i.e., in the situation where the filling with the target member TM reaches the tip end part 124c), the inside wall 123 has reached the tip end part 124c. Accordingly, the distance D7 to the inside wall 123 at the tip end part 124c is equal to the distance D6. As a result, in that situation, the distance D6 from the rotation axis R to the opening side cylindrical part 124a (the tip end part 124c included in the opening side cylindrical part 124a) is equal to or shorter than the distance D7 from the rotation axis R to the inside wall 123 (the distance D6 ≤ the distance D7). As explained herein, in the situation where the filling of the target member TM reaches the tip end part 124c of the protrusion part 124b, it is also conceivable to consider that the protrusion part 124b is not a part protruding at the cylindrical part 120.

In the situation where the direction of the opening 121 at which the cylindrical part 120 is open is the downward direction in the gravity directions, the opening side cylindrical part 124a may have a groove 129 recessed downward in the gravity directions. The groove 129 is able to hold the target member TM, when the centrifugal force caused by the rotation of the target holding unit 100 and acting on the target member TM becomes smaller than the gravity acting on the target member TM. As a result, it is possible to prevent the target member TM from falling and being lost.

### Modified Example 3-2

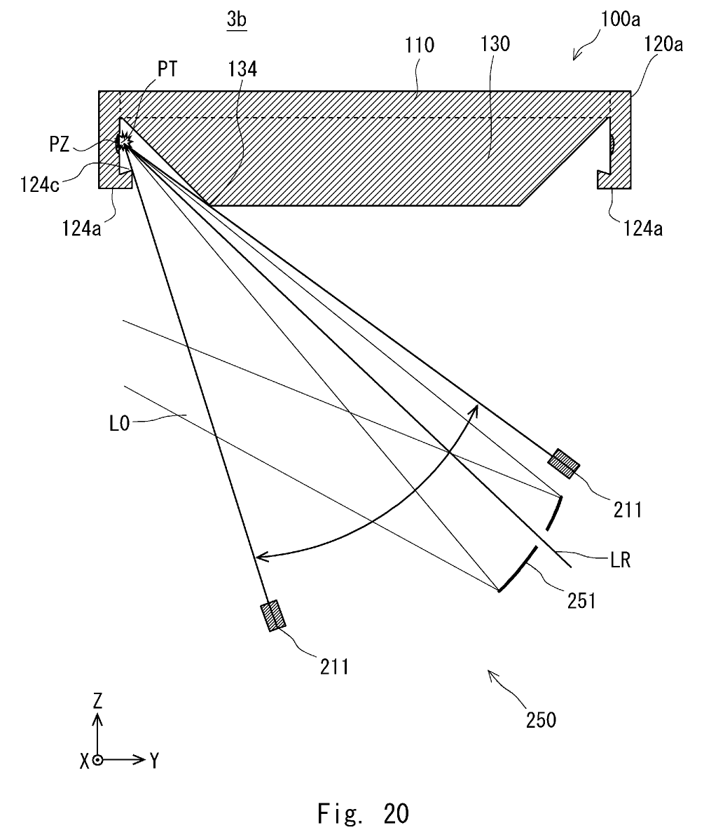

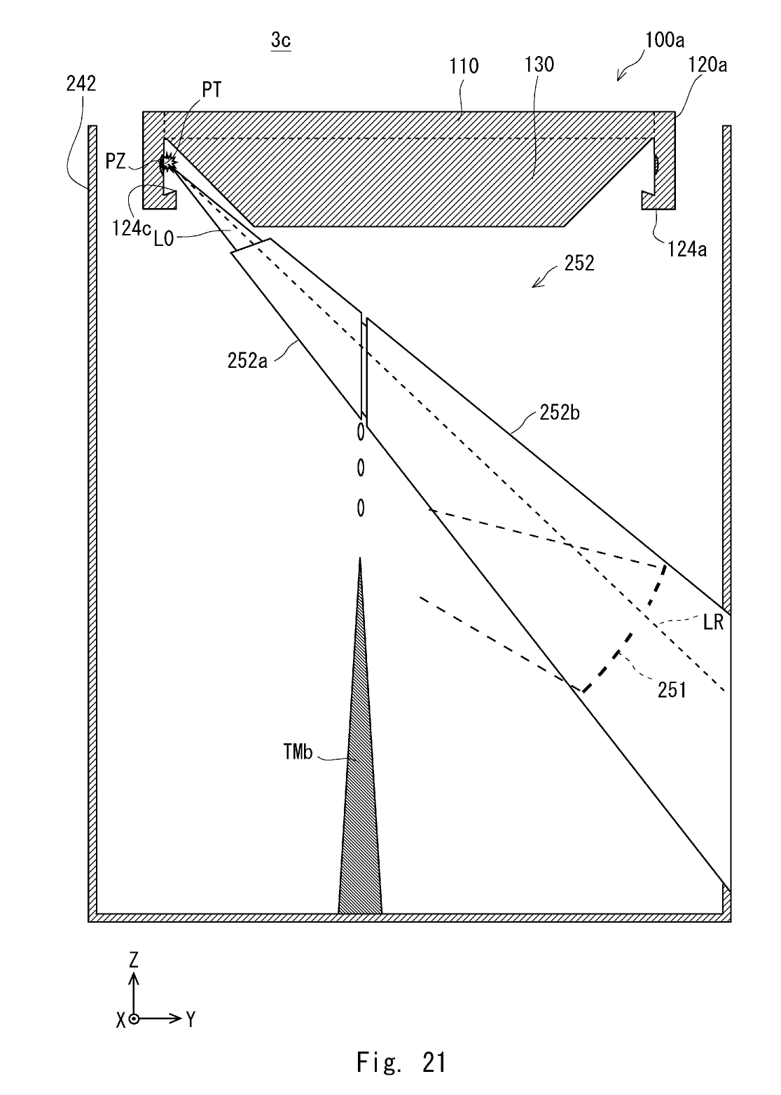

FIG. 20 is a cross-sectional view showing an example of a positional arrangement of the sensor 211 in a light source apparatus 3b according to a second modified example of the third embodiment. As shown in FIG. 20, the generated light L0 from the plasma PZ generated at the irradiation position PT is extracted from the light source apparatus 3b by the collector mirror 251 included in the output optical system 250. In the present modified example, the sensor 211 is disposed in at least one of a position for detecting the light L0 passing through the vicinity of the end part (e.g., the tip end part 124c) of the opening side cylindrical part 124a and a position for detecting the light L0 passing through the vicinity of the opening side end part 134.

With this positional arrangement, in the situation where the generated light L0 generated from the plasma PZ reaches the sensor 211, it is possible to determine that the bright point position is in a prescribed position. On the contrary, in the situation where the generated light L0 generated from the plasma PZ does not reach the sensor 211 because of being blocked by the opening side cylindrical part 124a (e.g., the tip end part 124c) or the opening side end part 134, it is possible to determine that the bright point position deviates from the prescribed position. Thus, it is possible to improve sensitivity for detecting deviations of the irradiation position PT.

Further, in FIG. 20, the light source apparatus 3b includes the target holding unit 100a having the cylindrical part 120a including the opening side cylindrical part 124a; however, the light source apparatus 3b may include the target holding unit 100 having the cylindrical part 120 including the opening side cylindrical part 124 not protruding in the direction toward the rotation axis R. In that situation, the sensor 211 is disposed in a position for detecting the light L0 passing through the vicinity of the end part of the opening side cylindrical part 124.

### Modified Example 3-3

FIG. 21 is a cross-sectional view showing an example of a debris storing container 242 in a light source apparatus 3c according to a third modified example of the third embodiment. FIG. 21 shows cross-sections of the target holding unit 100a and the debris storing container 242 and a side view of the optical path cover 252. As shown in FIG. 21, the light source apparatus 3c in the present modified example includes the debris storing container 242 in place of or in addition to the cover part 240. The debris storing container 242 has a bucket shape and is capable of storing scattered debris therein. Further, as described below, the debris storing container 242 is capable of storing therein a target member TMb in which debris have been gathered. As described herein, in the situation where the direction of the opening 121 at which the cylindrical part 120a is open is the downward direction in the gravity directions, the light source apparatus 3c may further include the debris storing container 242 which covers the opening side cylindrical part 124a from underneath. In FIG. 21, the light source apparatus 3c includes the target holding unit 100a having the cylindrical part 120a including the opening side cylindrical part 124a. However, the light source apparatus 3c may include the target holding unit 100 having the cylindrical part 120 including the opening side cylindrical part 124 not protruding in the direction toward the rotation axis R.

At least one of the optical path cover 222 and the optical path cover 252 may be disposed inside the debris storing container 242. Further, at least one of the optical path cover 222 and the optical path cover 252 may be disposed between the cylindrical part 120 and the debris storing container 242. In other words, the optical path cover 222 and the optical path cover 252 or the like may opt for at least one of: being attached to the cover part 240, being disposed inside the debris storing container 242, and being disposed between the cylindrical part 120 and the debris storing container 242. FIG. 21 depicts only the optical path cover 252. At least one of the optical path cover 222 and the optical path cover 252 may be divided into a plurality of segments. In the following sections, an example of the optical path cover 252 will be explained. The plurality of segments include, for example, a segment 252a and a segment 252b. A gap is formed between the segment 252a and the segment 252b. The optical path cover 252 may include a temperature adjustment mechanism such as a heater. The debris scattered from the irradiation position PT on the target member TM enter the inside of the optical path cover 252 and the like and adhere to the inner surface of the optical path cover 252 and the like. Also, the debris scattered from the irradiation position PT adhere to the outer surface of the optical path cover 252. The debris adhering to the optical path cover 252 in this manner are melted by the temperature adjustment mechanism, dribble down to the lower end of the segment 252a in the gravity directions, and falls from the lower end of the segment 252a. As a result, it is possible to gather, in a prescribed location, and retrieve the debris, as the target member TMb.

In this situation, possible methods for melting the debris adhering to the optical path cover 252 are not limited to the temperature adjustment mechanism. For example, it is also conceivable to melt the debris adhering to the optical path cover 252, by irradiating the optical path cover 252 with the excitation light LR, by shifting the optical axis of the excitation light LR passing through the inside of the optical path cover 252. The configurations and advantageous effects of the third embodiment and the modified examples thereof other than those described above are included in the description of the first and the second embodiments and the modified examples thereof.

### Fourth Embodiment

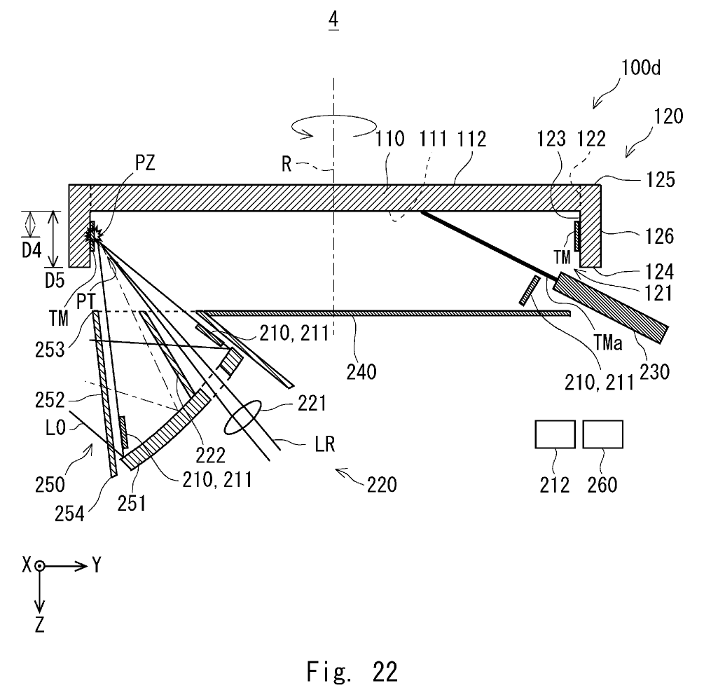

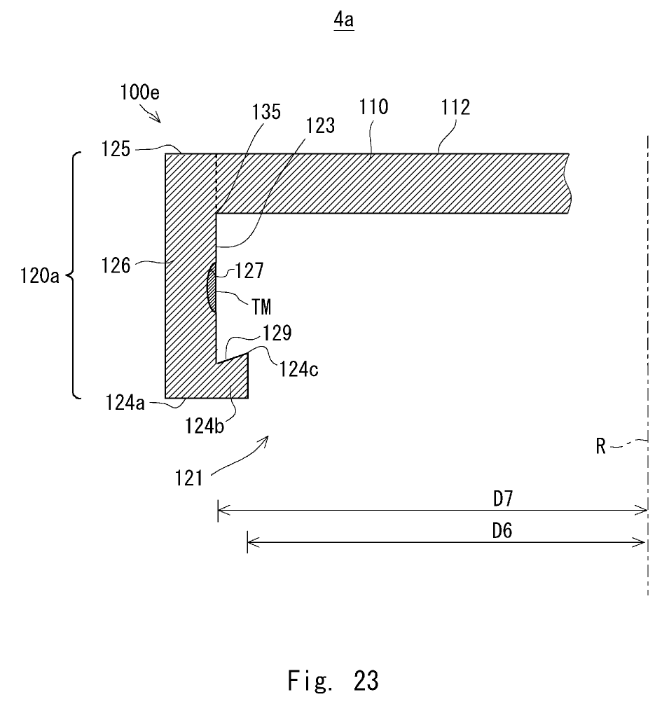

FIG. 22 is a cross-sectional view showing an example of a light source apparatus 4 according to a fourth embodiment. As shown in FIG. 22, the light source apparatus 4 according to the present embodiment includes a target holding unit 100d. The target holding unit 100d does not have the opposing part 130. The target holding unit 100d includes the bottom part 110 and the cylindrical part 120. One of the openings 121 of the cylindrical part 120 is open, whereas, the other opening 122 is contiguous with the bottom part 110. The inside wall 123 of the cylindrical part 120 holds the target member TM that generates the plasma PZ by being irradiated with the excitation light LR. The direction toward which the cylindrical part 120 is open is the downward direction in the gravity directions.

As explained above, the configuration of the light source apparatus 4 in the present embodiment is similar to that of the light source apparatus 3 in the third embodiment, except for not including the opposing part 130 included in the light source apparatus 3. In the light source apparatus 3 in the third embodiment, because the scattered debris fall due to gravity, it is possible to prevent the debris from being routed back to the inside wall 123. In the light source apparatus 2 in the second embodiment, the debris adhering to the opposing part 130 are returned from the opposing wall 133 to the inside wall 123 by the centrifugal force. Because the light source apparatus 4 in the present embodiment does not have the opposing part 130, the return from the opposing wall 133 to the inside wall 123 is not executed. The light source apparatus 4 in the fourth embodiment may be advantageous, depending on the balance between an impact of the fluctuation of the liquid surface which may be caused when the target member TM returns to the inside wall 123 by following along the opposing wall 133 and a consumption rate of the target member TM.

### Modified Example 4-1

FIG. 23 is a cross-sectional view showing an example of the cylindrical part 120a of a target holding unit 100e in a light source apparatus 4a according to a first modified example of the fourth embodiment. As shown in FIG. 23, in the light source apparatus 4a in the present modified example, the cylindrical part 120a of the target holding unit 100e includes the opening side cylindrical part 124a. In the present modified example also, the distance D6 from the rotation axis R to the opening side cylindrical part 124a is shorter than the distance D7 from the rotation axis R to the inside wall 123. Further, in the situation where the direction of the opening 121 at which the cylindrical part 120 is open is the downward direction in the gravity directions, the opening side cylindrical part 124a may have a groove 129 recessed downward. The configuration of the light source apparatus 4a in the present modified example is similar to the configuration of the light source apparatus 3a in the first modified example of the third embodiment, except for not having the opposing part 130 included in the light source apparatus 3a.

### Modified Example 4-2

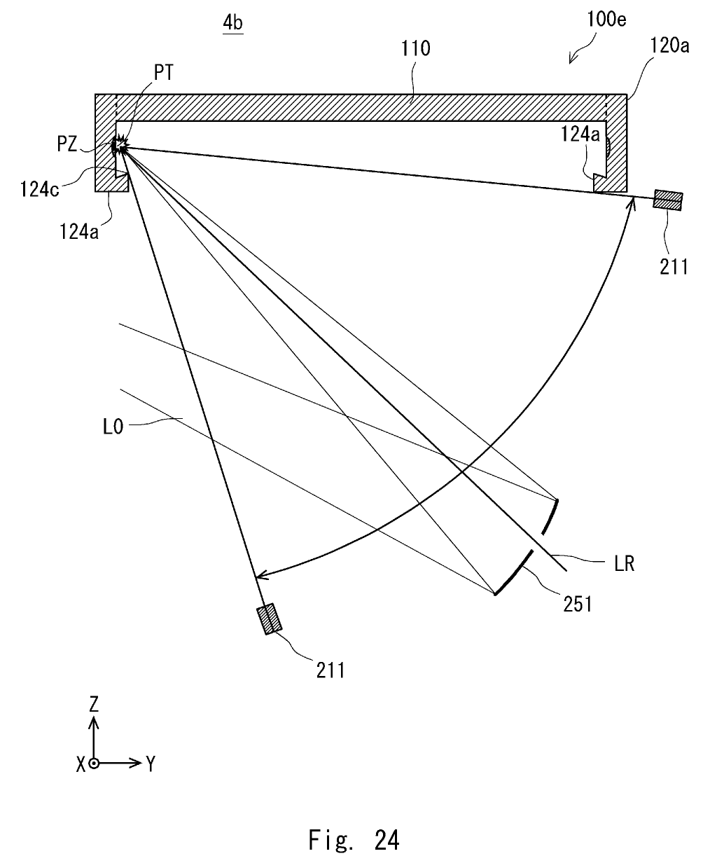

FIG. 24 is a cross-sectional view showing an example of a positional arrangement of the sensor 211 in a light source apparatus 4b according to a second modified example of the fourth embodiment. As shown in FIG. 24, the generated light L0 from the plasma PZ generated at the irradiation position PT is extracted from the light source apparatus 4b by the collector mirror 251. In the present modified example, the sensor 211 is disposed in a position for detecting the light L0 passing through the vicinity of the end part of the opening side cylindrical part 124a.

With this positional arrangement, in the situation where the generated light L0 generated from the plasma PZ reaches the sensor 211, it is possible to determine that the bright point position is in a prescribed position. On the contrary, in the situation where the generated light L0 generated from the plasma PZ does not reach the sensor 211 because of being blocked by the opening side cylindrical part 124a, it is possible to determine that the bright point position deviates from the prescribed position. Thus, it is possible to improve sensitivity for detecting deviations of the irradiation position PT.

Further, in FIG. 24, the light source apparatus 4b includes the target holding unit 100e having the cylindrical part 120a including the opening side cylindrical part 124a. However, the light source apparatus 4b may include the target holding unit 100d having the cylindrical part 120 including the opening side cylindrical part 124 not protruding in the direction toward the rotation axis R. In that situation, the sensor 211 is disposed in a position for detecting the light L0 passing through the vicinity of the end part of the opening side cylindrical part 124. The configuration of the light source apparatus 4b in the present modified example is similar to the configuration of the light source apparatus 3b in the second modified example of the third embodiment, except for not having the opposing part 130 included in the light source apparatus 3b.

### Modified Example 4-3

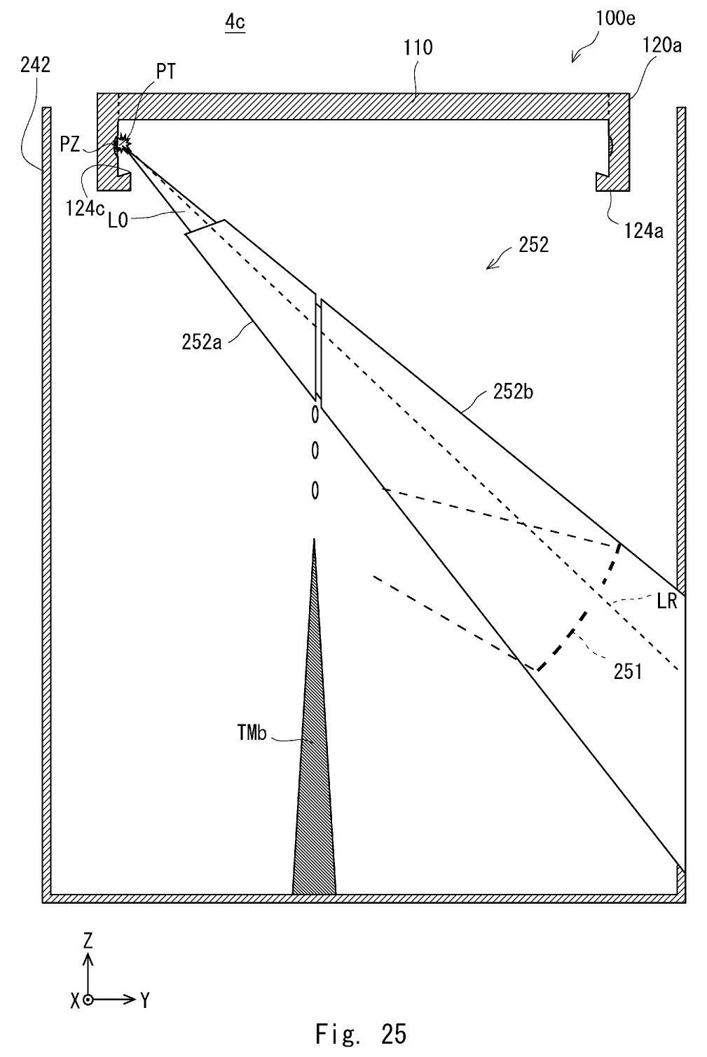

FIG. 25 is a cross-sectional view showing an example of the debris storing container 242 in a light source apparatus 4c according to a third modified example of the fourth embodiment. FIG. 25 shows cross-sections of the target holding unit 100e and the debris storing container 242 and a side view of the optical path cover 252. As shown in FIG. 25, the light source apparatus 4c in the present modified example includes the debris storing container 242 in place of or in addition to the cover part 240. As described herein, in the situation where the direction of the opening 121 at which the cylindrical part 120a is open is the downward direction in the gravity directions, the light source apparatus 3c may further include the debris storing container 242 which covers the opening side cylindrical part 124a from underneath. In FIG. 25, the light source apparatus 4c includes the target holding unit 100e having the cylindrical part 120a including the opening side cylindrical part 124a. However, the light source apparatus 4c may include the target holding unit 100d having the cylindrical part 120 including the opening side cylindrical part 124 not protruding in the direction toward the rotation axis R. The configuration of the light source apparatus 4c in the present modified example is similar to the configuration of the light source apparatus 3c in the third modified example of the third embodiment, except for not having the opposing part 130 included in the light source apparatus 3c.

In the third and the fourth embodiments, the direction of the opening 121 at which the cylindrical part 120 is open is the downward direction in the gravity directions. However, in a modified example of these embodiments, the direction of the opening 121 at which the cylindrical part 120 is open may be a horizontal direction orthogonal to the gravity directions or may be a direction tilted from the gravity directions. The configurations and advantageous effects of the fourth embodiment other than those described above are included in the description of the first to the third embodiments and the modified examples thereof.

### Fifth Embodiment

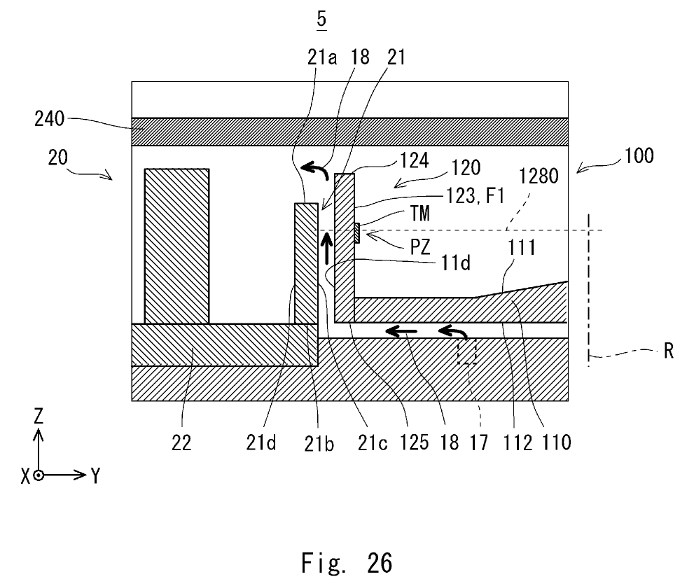

Next, a light source apparatus 5 according to a fifth embodiment will be explained. FIG. 26 is a cross-sectional view showing an example of the light source apparatus 5 according to the fifth embodiment. As shown in FIG. 26, the light source apparatus 5 includes a temperature adjustment unit 20 in addition to the target holding unit 100. The temperature adjustment unit 20 is configured to adjust temperatures of the target holding unit 100. In the light source apparatus 5 of the present embodiment, the target holding unit 100 includes a crucible. The hold plane F1 includes the inside wall 123 of the cylindrical part 120. In addition to the cylindrical part 120, the target holding unit 100 has the bottom part 110. The temperature adjustment unit 20 may include a cooling part. The temperature adjustment unit 20 includes an upright wall part 21 that functions as a cooling part connected to a heat sink or the like. The temperature adjustment unit 20 may further include a heat transfer part 22 that transfers heat. The upright wall part 21 may be connected to the heat sink or the like via the heat transfer part 22. In FIG. 26, the generation unit 220 and the output optical system 250 are omitted.

For example, the bottom part 110 has a plate-like shape and has the first surface 111 facing the +Z axis direction side and the second surface 112 facing the -Z axis direction side. The bottom part 110 is fitted into the bottom part cylindrical part 125 at the end part positioned on the -Z axis direction side so as to close the opening of the cylindrical part 120 positioned on the -Z axis direction side. In contrast, the opening side cylindrical part 124 at the end part of the cylindrical part 120 positioned on the +Z axis direction side is open. In the target holding unit 100, the inside wall 123 of the cylindrical part 120 serves as the hold plane F1. An outer circumferential surface 11d of the cylindrical part 120 opposes the upright wall part 21. The outer circumferential surface 11d opposing the upright wall part 21 may be referred to as an opposing surface, whereas the inside wall 123 on the opposite side from the opposing surface may be referred to as an opposite surface. Alternatively, the opposing surface (the outer circumferential surface 11d) of the cylindrical part 120 may be referred to as a cylindrical opposing surface, whereas the opposite surface (the inside wall 123) of the cylindrical part 120 may be referred to as a cylindrical opposite surface.

A first upright wall end part 21a at the end part of the upright wall part 21 on the +Z axis direction side is positioned on one of the sides (e.g., the +Z axis direction side) relative to the bottom part cylindrical part 125. With this configuration, it is possible to guarantee that the upright wall part 21 opposes at least a portion of the cylindrical part 120. Accordingly, the upright wall part 21 is able to adjust the temperature of the target holding unit 100. A second upright wall end part 21b of the upright wall part 21 may coincide, in the Z axis directions, with the bottom part cylindrical part 125. Further, the second upright wall end part 21b of the upright wall part 21 may be positioned, in the Z axis directions, on the one of the sides (the +Z axis direction) or on the other side (the -Z axis direction), relative to the bottom part cylindrical part 125. The second upright wall end part 21b of the upright wall part 21 may be connected to the heat transfer part 22. With this configuration, it is possible to maintain the temperature of the upright wall part 21 at a prescribed level.

The upright wall part 21 may intersect the normal line 1280 being orthogonal to the rotation axis R and passing through a formation point (the irradiation position PT) of the plasma PZ formed from the target member TM. In other words, the first upright wall end part 21a may be positioned on the +Z axis direction side relative to the plasma PZ, whereas the second upright wall end part 21b may be positioned on the -Z axis direction side relative to the plasma PZ. With this configuration, because the upright wall part 21 opposes the part of the cylindrical part 120 in a high temperature state, it is possible to adjust the temperature effectively. In the situation where the groove 127 is formed on the hold plane F1 along the circumference, the formation point of the plasma PZ may fall in the range of the groove 127 from the +Z axis direction side to the -Z axis direction side. As long as the upright wall part 21 opposes at least a portion of the cylindrical part 120, the upright wall part 21 does not necessarily need to include a part opposing the formation point of the plasma PZ.

The first upright wall end part 21a of the upright wall part 21 is positioned on the other side (the -Z axis direction) relative to the opening side cylindrical part 124. When the target member TM is irradiated with the excitation light LR, debris may be generated in some situations. The debris may migrate from the inside of the cylindrical part 120, jump over the opening side cylindrical part 124, and reach the outside of the target holding unit 100 in some situations. Also, droplets of the liquid splashing from the target member TM may migrate from the inside of the cylindrical part 120, jump over the opening side cylindrical part 124, and reach the outside of the target holding unit 100 in some situations. While the upright wall part 21 is functioning as a cooling part, if the debris or the droplets that jumped over the opening side cylindrical part 124 came into contact with the upright wall part 21, the debris or the droplets might be solidified on the upright wall part 21. In that situation, the solidified substance that has grown might come into contact with the target holding unit 100 and might prevent the target holding unit 100 from rotating in some situations.

In the present embodiment, because the first upright wall end part 21a of the upright wall part 21 is positioned on the -Z axis direction side relative to the opening side cylindrical part 124, it is possible to prevent the debris or the droplets that jumped over the opening side cylindrical part 124 from directly colliding with the upright wall part 21.

The cover part 240 covers at least a portion of the target holding unit 100 positioned on one of the sides. The interval between the cover part 240 and the cylindrical part 120 is smaller than the interval between the cover part 240 and the upright wall part 21. The cover part 240 may include, on the inside thereof, a heating unit such as a heater. Alternatively, the cover part 240 may be brought to a temperature equal to or higher than the melting point of the target member TM by radiant heat from the target member TM.

The light source apparatus 5 may further have an introduction unit 17. For example, the introduction unit 17 is configured to cause a gas 18 to jet out onto the second surface 112 of the bottom part 110 of the target holding unit 100. For example, the gas 18 may contain an inert gas such as nitrogen, argon, helium, or the like. Further, the gas 18 may contain a gas having a high thermal conductivity such as hydrogen, helium, or the like. The gas 18 introduced to the second surface 112 of the bottom part 110 from the introduction unit 17 passes between the cylindrical part 120 and the upright wall part 21 before being discharged from between the cylindrical part 120 and the first upright wall end part 21a. With this configuration, it is possible to prevent the debris or the droplets that jumped over the opening side cylindrical part 124 from colliding with the upright wall part 21.

The bottom part 110 of the target holding unit 100 may include a part in which the thickness in the rotation axis R direction (the Z axis direction) increases toward the rotation axis R side. More specifically, the thickness of the bottom part 110 may gradually become thicker toward the rotation axis R side. With this configuration, it is possible to prevent the target holding unit 100 from being deformed and to improve stability of the rotation of the target holding unit 100.

### Modified Example 5-1

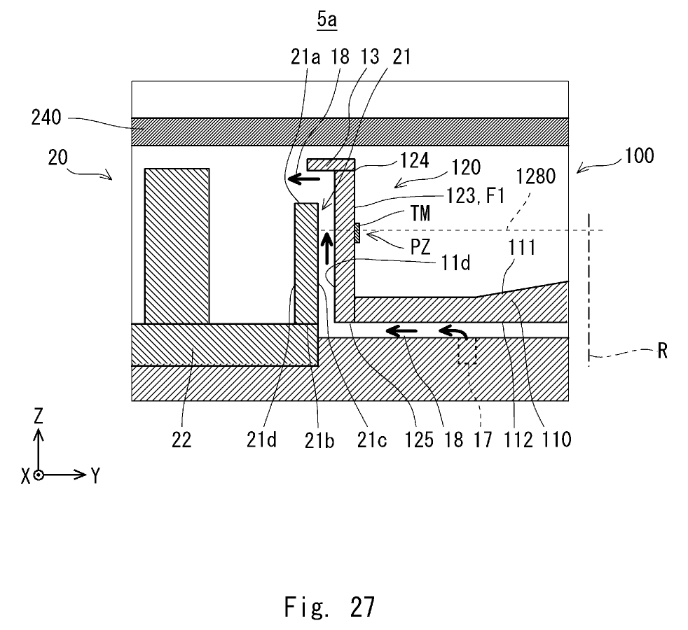

FIG. 27 is a cross-sectional view showing an example of a light source apparatus 5a according to a first modified example of the fifth embodiment. As shown in FIG. 27, in the light source apparatus 5a, the target holding unit 100 may further include a flange part 13. The flange part 13 is positioned on the +Z axis direction side of the cylindrical part 120. More specifically, the flange part 13 is attached to the opening side cylindrical part 124. The flange part 13 may include a part covering at least a portion of the first upright wall end part 21a.

Because the flange part 13 includes the part covering at least a portion of the first upright wall end part 21a, it is possible to prevent the debris or the droplets that jumped over the opening side cylindrical part 124 from directly colliding with the upright wall part 21. Further, the flange part 13 causes the gas 18 discharged from between the cylindrical part 120 and the first upright wall end part 21a to jet out in a direction away from the rotation axis R. Consequently, it is possible to prevent the debris or the droplets that jumped over the opening side cylindrical part 124 from directly colliding with the upright wall part 21.

Next, advantageous effects of the present embodiment will be explained. The light source apparatuses 5 and 5a in the present embodiment includes the temperature adjustment unit 20 including the upright wall part 21. As a result, it is possible to appropriately adjust the temperature of the target holding unit 100 and to prevent the target holding unit 100 from being deformed. By causing the upright wall part 21 to intersect the normal line 1280 passing through the formation point of the plasma PZ, it is possible to further appropriately adjust the temperature of the target holding unit 100. The other configurations and advantageous effects besides those described above are included in the description of the first to the fourth embodiments and the modified examples thereof.

Certain embodiments of the present disclosure have thus been explained. The present disclosure includes appropriate modifications that will not impair the purpose and advantages thereof and is not limited by the embodiments described above. Further, it is conceivable to combine, as appropriate, any of the configurations in the first to the fifth embodiments and the modified examples thereof.

The first to fifth embodiments can be combined as desirable by one of ordinary skill in the art.

From the disclosure thus described, it will be obvious that the embodiments of the disclosure may be varied in many ways. Such variations are not to be regarded as a departure from the spirit and scope of the disclosure, and all such modifications as would be obvious to one skilled in the art are intended for inclusion within the scope of the following claims.

What is claimed is:

1. A light source apparatus comprising:
a target holding unit having a hold plane for holding a target member that generates plasma by being irradiated with excitation light; and
a mirror opposing the plasma generated from the target member held on the hold plane and configured to reflect generated light generated from the plasma,
wherein the mirror has a missing part for passing an optical axis of the excitation light to be radiated onto the target member held on the hold plane or an extension line of the optical axis.

2. The light source apparatus according to claim 1, wherein:
a first focused point formed by the mirror corresponds to an irradiation position of the excitation light on the target member, and
a second focused point formed by the mirror corresponds to a position outside the target holding unit.

3. The light source apparatus according to claim 1, wherein:
the target member moves together with movement of the hold plane, and
the excitation light is radiated onto the target member at such an incident angle that an angle formed between a principal optical axis of the excitation light when the principal optical axis is projected on a plane and a straight line including a moving direction of the target member falls in a range of 0° to 60°, the plane including the moving direction of the target member on the hold plane at an irradiation position of the excitation light and a normal line to the hold plane.

4. The light source apparatus according to claim 1, wherein:
the target member moves together with movement of the hold plane, and
the excitation light is radiated onto the target member at such an incident angle that an angle formed between a principal optical axis of the excitation light when the principal optical axis is projected on a plane and a normal line to the hold plane at an irradiation position of the excitation light falls in a range of 0° to 10°, the plane including a moving direction of the target member on the hold plane at the irradiation position of the excitation light and the normal line to the hold plane.

5. The light source apparatus according to claim 1, wherein:
the mirror forms a first focused point corresponding to an irradiation position of the excitation light on the target member,
the target member moves together with movement of the hold plane, and
an angle formed between a straight line intersected by a plane and the hold plane at the irradiation position and a normal line to a straight line including a moving direction of the target member on the hold plane at the irradiation position falls in a range of 0° to 45°, the plane including a principal optical axis of the generated light traveling from the first focused point toward the mirror and a principal optical axis of the generated light reflected by the mirror.

6. The light source apparatus according to claim 5, wherein the principal optical axis of the generated light reflected by the mirror is positioned on an upper side in vertical directions relative to the plane.

7. The light source apparatus according to claim 5, wherein the principal optical axis of the generated light reflected by the mirror is positioned on a lower side in vertical directions relative to the plane.

8. The light source apparatus according to claim 1, wherein a principal optical axis of the excitation light to be radiated onto the target member does not overlap a principal optical axis of the generated light traveling from the plasma toward the mirror.

9. The light source apparatus according to claim 1, wherein a principal optical axis of the excitation light to be radiated onto the target member and a principal optical axis of the generated light traveling from the plasma toward the mirror have regions that substantially coincide with each other.

10. The light source apparatus according to claim 1, wherein an angle formed between a direction orthogonal to the hold plane at an irradiation position of the excitation light and the optical axis of the excitation light is smaller than an angle formed between the direction orthogonal to the hold plane at the irradiation position and an optical axis of the generated light traveling from the plasma toward the mirror.

11. The light source apparatus according to claim 1, wherein a portion of an outer circumferential surface of an excitation light cover covering at least a portion of an optical path of the excitation light is in contact with a portion of an inner circumferential surface of a generated light cover covering at least a portion of an optical path of the generated light.

12. The light source apparatus according to claim 1, further comprising a filter that is in contact with an outer circumferential surface of an excitation light cover covering at least a portion of an optical path of the excitation light and with an inner circumferential surface of a generated light cover covering at least a portion of an optical path of the generated light.

13. The light source apparatus according to claim 1, wherein:
the hold plane moves as a result of the target holding unit rotating on a rotation axis, and
the target member moves to an irradiation position of the excitation light in conjunction with the moving of the hold plane.
